(19) United States
(12) Patent Application Publication
(10) Pub. No.: US 2016/0131974 A1
(43) Pub. Date: May 12, 2016

(54) METHOD OF MANUFACTURING TRANSPARENT SUBSTRATE PROVIDED WITH CURED FILM, PHOTOSENSITIVE RESIN COMPOSITION, PHOTOSENSITIVE ELEMENT, AND ELECTRICAL COMPONENT

(71) Applicant: HITACHI CHEMICAL COMPANY, LTD., Tokyo (JP)

(72) Inventors: Koji ABE, Chiyoda-ku, Tokyo (JP); Ikuo MUKAI, Chiyoda-ku, Tokyo (JP); Mayumi SATO, Chiyoda-ku, Tokyo (JP)

(21) Appl. No.: 14/895,594

(22) PCT Filed: Jun. 3, 2014
(86) PCT No.: PCT/JP2014/064779

§ 371 Date: Dec. 3, 2015

(30) Foreign Application Priority Data
Jun. 4, 2013 (JP) 2013-118318

(51) Int. Cl. G03F 7/033; G03F 7/20

(52) U.S. Cl. CPC G03F 7/033; G03F 7/20

(57) ABSTRACT

The method of manufacturing a transparent base material provided with a cured film according to the present invention is characterized in that a photosensitive layer composed of a photosensitive resin composition containing a binder polymer, a photopolymerizable compound containing at least one (meth)acrylate compound selected from the group consisting of (meth)acrylate compounds having a skeleton derived from ditrimethylolpropane and (meth)acrylate compounds having a skeleton derived from diglycerol, and a photopolymerization initiator is disposed on a transparent base material, a predetermined portion of the photosensitive layer is cured through irradiation with active light rays, and portions of the photosensitive layer other than the predetermined portion are then removed to form a cured film composed of a cured product of the photosensitive resin composition, the cured film coating part or all of the base material.

### TECHNICAL FIELD

The present invention relates to a method of manufacturing a transparent base material provided with a cured film, a photosensitive resin composition and a photosensitive element used in the method, and an electrical component.

### BACKGROUND ART

Liquid crystal display elements or touch panels (touch sensors) are used in display apparatuses of large electronic apparatuses such as personal computers and televisions, small electronic apparatuses such as car navigation systems, mobile phones, and electronic dictionaries, and OA and FA apparatuses. These liquid crystal display elements or touch panels are provided with electrodes composed of transparent conductive electrode materials. Indium tin oxide (ITO), indium oxide, or tin oxide is known as the transparent conductive electrode materials. These materials exhibit high visible light transmittance, and therefore are popular as an electrode material used in substrates for liquid crystal display elements and the like.

The touch panels of various systems are already practically used. Recently, use of capacitive touch panels has been promoted. In the capacitive touch panels, when a fingertip as a conductor contacts a touch input screen, capacitance is combined between the fingertip and a conductive film to form a capacitor. For this reason, the capacitive touch panels capture a change in charge in the contact position of the fingertip to detect the coordinate.

In particular, because projected capacitive touch panels can detect the fingertip at several points, the projected capacitive touch panels have excellent operationability enabling performance of complex instructions. The projected capacitive touch panels have been promoted, because of their excellence of operationability, in use as input devices disposed on display screens in apparatuses having small display devices such as mobile phones and portable music players.

In general, in the projected capacitive touch panels, a plurality of X electrodes and a plurality of Y electrodes orthogonal to the X electrodes are formed into a two-layer structure to express a two-dimensional coordinate of an X-axis and a Y-axis. As these electrodes, ITO is used.

The frame regions of the touch panels are regions in which the touch location cannot be detected; therefore, a reduction in the area of the frame region is an important factor to increase the product value. The frame region requires metal wiring to transmit the detection signal of the touch location while the width of the metal wiring needs to be reduced to reduce the frame area. In general, copper is used for the metal wiring.

However, in the touch panels as described above, corrosive components such as moisture and salt may intrude into the touch panels from the sensing regions when the touch panels are in contact with the fingertip. If corrosive components intrude into the touch panels, the metal wiring may corrode to increase the electric resistance between the electrodes and driving circuits or cause disconnection.

A projected capacitive touch panel having a cured film such as an insulation film formed on a metal to prevent corrosion of metal wiring is disclosed (for example, Patent Literature 1). In this touch panel, a silicon dioxide layer is formed on a metal by plasma chemical vapor deposition (plasma CVD), preventing corrosion of the metal. However, because this method uses plasma CVD, this method requires a treatment at high temperature, leading to problems such as limitation of base materials and increased production cost.

As a method of disposing a cured film such as a resist film in a desired place, a method of disposing a photosensitive layer composed of a photosensitive resin composition on a predetermined base material, and exposing and developing the photosensitive layer is known (for example, Patent Literatures 2 to 4).

### CITATION LIST

### Patent Literature

Patent Literature 1: Japanese Patent Application Laid-Open No. 2011-28594
Patent Literature 2: Japanese Patent Application Laid-Open No. 7-253666
Patent Literature 3: Japanese Patent Application Laid-Open No. 2005-99647
Patent Literature 4: Japanese Patent Application Laid-Open No. 11-133617

### SUMMARY OF INVENTION

### Technical Problem

A reduction in cost can be expected in preparation of the cured film using a photosensitive resin composition compared to preparation of that by plasma CVD. Unfortunately, if a cured film is formed on a transparent base material such as a base material for a touch panel and the cured film has a large thickness, the difference in level between places having the film and those having no film may be remarkable. For this reason, it is preferred that the cured film be formed as thin as possible. However, no example has been found in which anti-corrosive properties of films formed from photosensitive resin compositions are examined at a level of a thickness of 10 μm or less.

Moreover, a load may be applied to the touch panel itself during the process of manufacturing the touch panel. In particular, if a cured film such as a protective film is disposed on a flexible display substrate, a load on the cured film such as a protective film is increased with bending of the substrate, readily causing crack.

An object of the present invention is to provide a method of manufacturing a transparent base material provided with a cured film which has a cured film on a predetermined transparent base material, the cured film having desired film properties and high crack resistance even if the cured film is a thin film, a photosensitive resin composition and a photosensitive element enabling formation of such a cured film, and an electrical component comprising a transparent base material provided with a cured film.

### Solution to Problem

The present inventors, who have conducted extensive research to solve the above problems, have found that a photosensitive resin composition containing a binder polymer, a specific photopolymerizable compound, and a photopolymerization initiator has sufficient developability, and that a film formed by photocuring has sufficient anti-corrosive properties even if the film is a thin film (for example, 10 μm or less), can sufficiently prevent corrosion of a metal such as copper, and has high crack resistance, and thus have completed the present invention.

The method of manufacturing a transparent base material provided with a cured film according to the present invention is characterized in that a photosensitive layer composed of a photosensitive resin composition containing a binder polymer, a photopolymerizable compound containing at least one (meth)acrylate compound selected from the group consisting of (meth)acrylate compounds having a skeleton derived from ditrimethylolpropane and (meth)acrylate compounds having a skeleton derived from diglycerol, and a photopolymerization initiator is disposed on a transparent base material, a predetermined portion of the photosensitive layer is cured through irradiation with active light rays, and portions of the photosensitive layer other than the predetermined portion are then removed to form a cured film composed of a cured product of the photosensitive resin composition, the cured film coating part or all of the base material.

According to the method of manufacturing a transparent base material provided with a cured film according to the present invention, use of the specific photosensitive resin composition can manufacture a transparent base material provided with a cured film which has a cured film ensuring developability and adhesion to the base material, having desired film properties (particularly, sufficient anti-corrosive properties) even if the cured film is a thin film of 10 μm or less, and having high crack resistance. According to the present invention, the cured film can be in the form of a thin film, and thus electrical components (such as touch panels) having good appearances can be manufactured, and a reduction in production cost can be achieved.

From the viewpoint of a further enhancement in film properties (particularly anti-corrosive properties), it is preferred that the (meth)acrylate compound be a compound having four or more (meth)acryloyl groups.

Considering the visibility or good appearance of the electrical components such as touch panels, it is desired that the cured film have high transparency. However, the present inventors have also found that resolution property tends to reduce if a photosensitive layer composed of a highly transparent thin film is patterned. The present inventors believe that this is caused because as the thickness of the photosensitive layer is reduced, such a photosensitive layer is more readily affected by light scattering from the base material to generate halation.

In contrast, in the present invention, the photopolymerization initiator contains an oxime ester compound and/or a phosphine oxide compound, thereby enabling formation of a pattern with sufficient resolution.

The present inventors infer the reason why the above effect is obtained as follows: the oxime moiety contained in the oxime ester compound or the phosphine oxide moiety contained in the phosphine oxide compound has relatively high photodecomposition efficiency and has a suitable threshold such that the moiety does not decompose with a small amount of leaked light, and therefore the influences by the leaked light is prevented.

In the method of manufacturing a transparent base material provided with a cured film according to the present invention, a photosensitive element comprising a support film and a photosensitive layer composed of the photosensitive resin composition and disposed on the support film can be prepared, and the photosensitive layer of the photosensitive element can be transferred onto the base material to dispose the photosensitive layer. In this case, use of the photosensitive element can greatly contribute to a reduction in the manufacturing process and a reduction in cost, for example, can easily implement the roll-to-roll process or can reduce a solvent drying step.

The present invention also provides a photosensitive resin composition comprising a binder polymer, a photopolymerizable compound containing at least one (meth)acrylate compound selected from the group consisting of (meth)acrylate compounds having a skeleton derived from ditrimethylolpropane and (meth)acrylate compounds having a skeleton derived from diglycerol, and a photopolymerization initiator, and used to form a cured film on a transparent base material (used in the method of manufacturing a transparent base material provided with a cured film).

According to the photosensitive resin composition according to the present invention, a cured film having desired film properties (particularly, sufficient anti-corrosive properties) and crack resistance even if the cured film is a thin film can be formed on a predetermined transparent base material.

From the viewpoint of a further enhancement in film properties (particularly, anti-corrosive properties), it is preferred that the (meth)acrylate compound be a compound having four or more (meth)acryloyl groups.

In the photosensitive resin composition according to the present invention, it is preferred that the photopolymerization initiator contain an oxime ester compound and/or a phosphine oxide compound. In this case, a cured film with a pattern having sufficient resolution can be formed in the form of a highly transparent thin film.

The present invention also provides a photosensitive element comprising a support film and a photosensitive layer composed of the photosensitive resin composition according to the present invention and disposed on the support film.

According to the photosensitive element according to the present invention, a cured film having desired film properties (particularly high anti-corrosive properties) and crack resistance even if the cured film is a thin film can be formed on a predetermined transparent base material.

The thickness of the photosensitive layer can be 10 μm or less.

The present invention also provides an electrical component comprising the transparent base material provided with a cured film according to the present invention.

### Advantageous Effects of Invention

According to the present invention, a method of manufacturing a transparent base material provided with a cured film which has a cured film on a predetermined transparent base material, the cured film having desired film properties (particularly, sufficient anti-corrosive properties) and crack resistance even if the cured film is a thin film, a photosensitive resin composition and a photosensitive element enabling formation of such a cured film, and an electrical component comprising a transparent base material provided with a cured film.

Moreover, according to the present invention, metal electrodes of capacitive touch panels can be protected. Furthermore, according to the present invention, electrodes can be protected in frame regions of the touch panels having conductivity enhanced by forming a metal layer made of copper or the like, which readily rusts due to moisture, salt, and the like.

### BRIEF DESCRIPTION OF DRAWINGS

FIG. 1 is a schematic sectional view illustrating one embodiment of the photosensitive element according to the present invention.

FIG. 2(a) and FIG. 2(b) are schematic sectional views for describing one embodiment of the method of manufacturing a base material for touch panels provided with the protective film according to the present invention, and FIG. 2(c) is a schematic sectional view of a base material for touch panels provided with the protective film according to one embodiment of the present invention.

FIG. 3 is a schematic top view illustrating one example of a capacitive touch panel.

FIG. 4 is a schematic top view illustrating another example of a capacitive touch panel.

FIG. 5(a) is a partial sectional view of a portion C taken along line V-V shown in FIG. 3, and FIG. 5(b) is a partial sectional view illustrating another aspect thereof.

FIG. 6 is a plan view illustrating one example of a capacitive touch panel having transparent electrodes present on the same plane.

FIG. 7 is a partially cutout perspective view illustrating one example of a capacitive touch panel having transparent electrodes present on the same plane.

FIG. 8 is a partial sectional view taken along line VI-VI in FIG. 7.

FIG. 9(a) and FIG. 9(b) are drawings for describing one example of a method of manufacturing a capacitive touch panel having transparent electrodes present on the same plane; FIG. 9(a) is a partially cutout perspective view illustrating a substrate including transparent electrodes, and FIG. 9(b) is a partially cutout perspective view illustrating the resulting capacitive touch panel.

FIG. 10(a), FIG. 10(b), and FIG. 10(c) are drawings for describing a method of manufacturing a capacitive touch panel having transparent electrodes present on the same plane; FIG. 10(a) is a partial sectional view taken along line VIIIa-VIIIa in FIG. 9, FIG. 10(b) is a partial sectional view illustrating a step of disposing an insulation film, and FIG. 10(c) is a partial sectional view taken along line VIIIc-VIIIc in FIG. 7.

FIG. 11 is a partial plan view illustrating one example of a touch panel having an insulation film disposed on a transparent electrode wiring and a drawing wiring disposed thereon, the transparent electrode being connected to the drawing wiring via an opening.

### DESCRIPTION OF EMBODIMENTS

Embodiments for implementing the present invention will now be described in detail. The present invention, however, will not be limited to the embodiments below.

Throughout the specification, “(meth)acrylic acid” indicates acrylic acid or methacrylic acid, “(meth)acrylate” indicates acrylate or methacrylate, and “(meth)acryloyl group” indicates an acryloyl group or a methacryloyl group.

Throughout the specification, the term “step” involves not only independent steps, but also cases which are not clearly distinguished from other steps but attain intended action of the steps. Throughout the specification, the numeric range specified using the term “to” indicates a range in which the numeric values before and after the term “to” are inclusive as the lower limit and the upper limit, respectively.

Throughout the specification, the content of each component in the composition indicates the total amount of a plurality of substances corresponding to each component in the composition if such substances are present in the composition, unless otherwise specified.

In the method of manufacturing a transparent base material provided with a cured film according to the present embodiment, a photosensitive layer comprising the photosensitive resin composition according to the present invention is disposed on a transparent base material, a predetermined portion of the photosensitive layer is cured through irradiation with active light rays, and portions of the photosensitive layer other than the predetermined portion are then removed to form a cured film (namely, resin cured film) composed of a cured product of the photosensitive resin composition, the cured film coating part or all of the base material. The photosensitive resin composition according to the present invention contains a binder polymer, a photopolymerizable compound containing a specific (meth)acrylate compound described later, and a photopolymerization initiator.

Examples of the transparent base material include substrates such as glass plates such as super white glass, float glass, and silica-coated float glass; plastic substrates made of poly(ethylene terephthalate), polycarbonate, and cycloolefin polymer; and ceramic plates. The transparent base material preferably has a minimum light transmittance of 85% or more in a wavelength band of 400 to 700 nm.

Throughout the specification, the cured film formed on the transparent base material can be disposed on a sensing region having electrodes, a frame region having metal wiring, or other regions if the cured film is used in a base material for touch panels. The cured film formed on the base material for touch panels may be disposed on only any of these regions, or may be disposed on two or more of the regions. Alternatively, the cured film can be disposed on part of electrodes formed in the sensing region, for example; in short, the position and range of the cured film disposed can be appropriately selected according to the purpose of use or the like.

The photosensitive layer can be disposed by preparing a photosensitive element comprising a support film and a photosensitive layer comprising the photosensitive resin composition and disposed on the support film, and transferring the photosensitive layer of the photosensitive element onto the transparent base material.

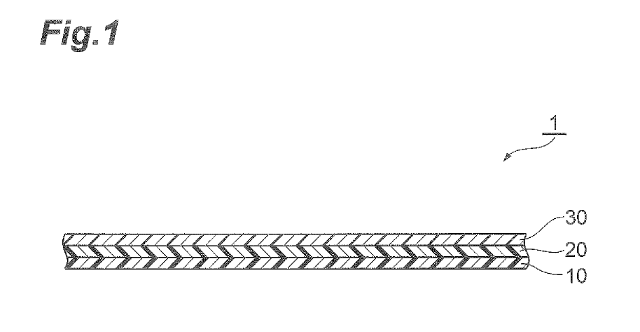

FIG. 1 is a schematic sectional view illustrating one embodiment of the photosensitive element according to the present invention. A photosensitive element 1 illustrated in FIG. 1 is composed of a support film 10, a photosensitive layer 20 composed of the photosensitive resin composition according to the present invention and disposed on the support film, and a protection film 30 disposed on the photosensitive layer 20 opposite to the support film 10.

The photosensitive element 1 according to the present embodiment can be used to form a cured film on a transparent base material, and can be suitably used to form a protective film for base materials for touch panels.

As the support film 10, polymer films can be used. Examples of the polymer films include films made of poly(ethylene terephthalate), polycarbonate, polyethylene, polypropylene, and polyethersulfone.

The thickness of the support film 10 is preferably 5 to 100 μm, more preferably 10 to 70 μm, still more preferably 15 to 60 μm from the viewpoint of ensuring the coating properties and preventing a reduction in resolution during exposure through the support film.

The photosensitive resin composition according to the present invention forming the photosensitive layer 20 contains a binder polymer (hereinafter also referred to as component (A)), a photopolymerizable compound (hereinafter also referred to as component (B)) containing at least one (meth)acrylate compound selected from the group consisting of (meth)acrylate compounds having a skeleton derived from ditrimethylolpropane and (meth)acrylate compounds having a skeleton derived from diglycerol, and a photopolymerization initiator (hereinafter also referred to as component (C)).

According to the photosensitive resin composition according to the present embodiment, while developability and adhesion to the transparent base material are ensured, a cured film having a thickness of 10 μm or less and desired film properties (particularly, sufficient anti-corrosive properties) and crack resistance can be formed.

In the present embodiment, the component (A) is suitably a copolymer containing a structural unit derived from (meth)acrylic acid (a1) and a structural unit derived from alkyl(meth)acrylate ester (a2).

Examples of alkyl(meth)acrylate esters (a1) include methyl(meth)acrylate ester, ethyl(meth)acrylate ester, butyl(meth)acrylate ester, 2-ethylhexyl(meth)acrylate ester, and hydroxylethyl(meth)acrylate ester.

Examples of alkyl(meth)acrylate esters (a2) include methyl(meth)acrylate ester, ethyl(meth)acrylate ester, butyl(meth)acrylate ester, 2-ethylhexyl(meth)acrylate ester, and hydroxylethyl(meth)acrylate ester.

The copolymer may contain other monomers copolymerizable with the component (a1) and/or the component (a2) in the structural unit.

Examples of the other monomers copolymerizable with the component (a1) and/or the component (a2) include tetrahydrofurfuryl(meth)acrylate ester, dimethylaminoethyl(meth)acrylate ester, diethylaminoethyl(meth)acrylate ester, glycidyl(meth)acrylate ester, benzyl(meth)acrylate ester, 2,2,2-trifluoroethyl(meth)acrylate, 2,2,3,3-tetrafluoropropyl(meth)acrylate, acrylamide, acrylonitrile, diacetoneacrylamide, styrene, and vinyl toluene. During synthesis of a binder polymer as the component (A), these monomers can be used singly or in combinations of two or more.

The molecular weight of the binder polymer as the component (A) is not particularly limited; in view of applicability, strength of coatings, and developability, usually, the weight average molecular weight (value measured by GPC in terms of standard polystyrene) is preferably 10000 to 200000, more preferably 30000 to 150000, extremely preferably 50000 to 100000. The conditions on the measurement of the weight average molecular weight are the same as those in Examples in the specification of the present application.

The acid value of the binder polymer as the component (A) is preferably 30 to 150 mgKOH/g, more preferably 40 to 120 mgKOH/g, extremely preferably 50 to 100 mgKOH/g. If the acid value of the component (A) is 30 mgKOH/g, development is achieved with various known developing solutions in a developing step through a step of selectively removing the photosensitive resin composition layer to form the pattern. If the acid value of the component (A) is 150 mgKOH/g or less, the cured film serving as a protective film for the base material, electrodes, and the like can have sufficiently enhanced resistance against the corrosive components such as moisture and salt.

The acid value of the binder polymer can be measured as follows. Namely, first, after 1 g of a binder polymer whose acid value is to be measured is precisely weighed, 30 g of acetone is added to the polymer to uniformly dissolve the polymer. If the binder polymer contains a volatile component such as a synthetic solvent or a diluted solvent, the binder polymer is preheated at a temperature about 10° C. higher than the boiling point of the volatile component for 1 to 4 hours to remove the volatile component. Next, a proper amount of phenolphthalein as an indicator is added to the solution to perform titration using an aqueous solution of 0.1 N potassium hydroxide (KOH). The number of milligrams of KOH needed to neutralize the target acetone solution of the binder polymer is calculated from the following expression to determine the acid value:

acid value=0.1×Vf×56.1/(Wp×I/100)

where Vf represents the amount (mL) of KOH used in titration; Wp represents the weight (g) of the solution containing the binder polymer measured; I represents the proportion (% by mass) of a non-volatile component in the solution containing the binder polymer measured.

In the conventional photosensitive element in which film properties are considered, a photosensitive layer is usually formed in a thickness of more than 10 μm; to ensure developability at this time, the acid value of the binder polymer contained in the photosensitive resin composition used is adjusted. Usually, the acid value is set at a value of about 140 to 250 mgKOH/g. If a cured film having a thickness of 10 μm or less is formed on a base material using such a photosensitive resin composition, sufficient anti-corrosive properties were not able to be obtained. The present inventors infer that this is because in such a thin film of 10 μm or less, corrosive components such as moisture and salt are readily contained in the film, and additionally this tendency is enhanced by the carboxyl group contained in the binder polymer. If the acid value is significantly small, ensuring sufficient developability and adhesion to the base material tends to be difficult; in contrast, anti-corrosive properties, crack resistance, and developability can be compatible at a higher level by a combination of the component (A) having an appropriate acid value and the component (B) which can further enhance the anti-corrosive properties.

If the acid value of the binder polymer is 30 to 150 mgKOH/g, development can be performed using an alkali aqueous solution containing water, an alkali metal salt, and a surfactant. At an acid value of 30 mgKOH/g or more, developability can be enhanced; at an acid value of 150 mgKOH/g or less, the function of the cured film as a protective film can be sufficiently demonstrated.

If development is performed using an alkali aqueous solution of sodium carbonate, potassium carbonate, tetramethylammonium hydroxide, or triethanolamine, for example, it is more preferred that the acid value be 50 to 120 mgKOH/g. For high developability, an acid value of 50 mgKOH/g or more is preferred; from the viewpoint of protecting electrodes from the corrosive components such as moisture and salt in protection of the transparent base material, an acid value of 100 mgKOH/g or less is particularly preferred.

The photopolymerizable compound as the component (B) comprises at least one (meth)acrylate compound selected from the group consisting of (meth)acrylate compounds having a skeleton derived from ditrimethylolpropane and (meth)acrylate compounds having a skeleton derived from diglycerol.

Examples of the (meth)acrylate compounds having a skeleton derived from ditrimethylolpropane include compounds represented by the following formula (1):

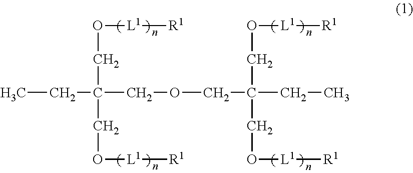

where R¹ represents a hydrogen atom or a (meth)acryloyl group; L¹ represents an alkyleneoxy group; and n represents an integer of 0 or 1. Four R¹ may be the same or different, and at least two of them are (meth)acryloyl groups. As the alkyleneoxy group, an ethyleneoxy group or a propyleneoxy group is preferred.

Examples of the (meth)acrylate compounds having a skeleton derived from diglycerol include compounds represented by the following formula (2):

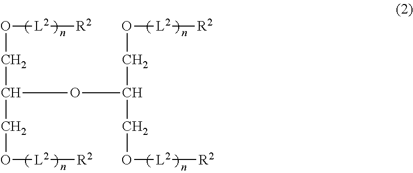

where R² represents a hydrogen atom or a (meth)acryloyl group; L² represents an alkyleneoxy group; and n represents an integer of 0 or 1. Four R² may be the same or different, and at least two of them are (meth)acryloyl groups. As the alkyleneoxy group, an ethyleneoxy group or a propyleneoxy group is preferred.

Among the compounds represented by the above formula (1), ditrimethylolpropane tetraacrylate represented by the following formula (3) is most preferred. Ditrimethylolpropane tetraacrylate is commercially available as T-1420(T) (manufactured by NIPPON KAYAKU Co., Ltd., trade name).

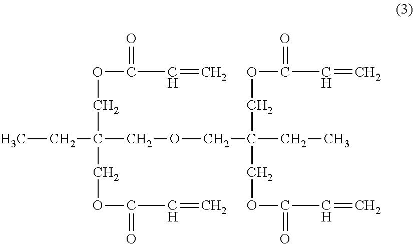 [SMILES: C=CC(=O)OCC(CC)(COCC(CC)(COC(=O)C=C)COC(=O)C=C)COC(=O)C=C]

Here, the (meth)acrylate compound having a skeleton derived from ditrimethylolpropane can be obtained, for example, through esterification of ditrimethylolpropane and (meth)acrylic acid or transesterification using a neutral catalyst. The compound includes compounds modified with an alkyleneoxy group. The compound preferably has two or more ester bonds in one molecule; compounds having 2 to 4 ester bonds may be mixed.

The (meth)acrylate compound having a skeleton derived from diglycerol can be obtained, for example, through esterification of diglycerol and (meth)acrylic acid or transesterification using a neutral catalyst. The compound includes compounds modified with an alkyleneoxy group. The compound preferably has two or more ester bonds in one molecule; compounds having 2 to 4 ester bonds may be mixed.

From the viewpoint of a reduction in corrosion of electrodes and a further enhancement in readiness in development, it is preferred that the (meth)acrylate compound having a skeleton derived from ditrimethylolpropane, and (meth)acrylate compound having a skeleton derived from diglycerol include at least one compound selected from alkylene oxide-modified ditrimethylolpropane di(meth)acrylate compounds, alkylene oxide-modified ditrimethylolpropane tri(meth)acrylate compounds, alkylene oxide-modified tetra(meth)acrylate compounds, alkylene oxide-modified diglycerol di(meth)acrylate compounds, alkylene oxide-modified diglycerol tri(meth)acrylate compounds, and alkylene oxide-modified diglycerol tetra(meth)acrylate compounds, and it is more preferred that the (meth)acrylate compound having a skeleton derived from ditrimethylolpropane, (meth)acrylate compound having a skeleton derived from diglycerol include at least one compound selected from alkylene oxide-modified ditrimethylolpropane tetra(meth)acrylate compounds and alkylene oxide-modified diglycerol tetra(meth)acrylate compounds.

These compounds can be used singly or in combinations of two or more.

For the contents of the component (A) and the component (B) in the photosensitive resin composition according to the present embodiment, it is preferred that the component (A) be 40 to 80 parts by mass and the component (B) be 20 to 60 parts by mass relative to 100 parts by mass of the total amount of the component (A) and the component (B), it is more preferred that the component (A) be 50 to 70 parts by mass and the component (B) be 30 to 50 parts by mass relative to 100 parts by mass of the total amount of the component (A) and the component (B), and it is still more preferred that the component (A) be 55 to 65 parts by mass and the component (B) be 35 to 45 parts by mass relative to 100 parts by mass of the total amount of the component (A) and the component (B).

At a content of the component (A) within this range, applicability or film properties in the photosensitive element are sufficiently ensured while sufficient sensitivity can be obtained and photo-curability can be sufficiently ensured.

The photosensitive resin composition according to the present embodiment can contain a photopolymerizable compound other than the component (B). As a photopolymerizable compound, the component (B) can be used in combination with one or more monofunctional monomers and polyfunctional monomers, for example. Examples of the monofunctional monomers include (meth)acrylic acid and alkyl(meth)acrylate esters listed as suitable monomers used in synthesis of the binder polymer in the component (A), and monomers copolymerizable therewith.

Examples of the polyfunctional monomers include polyethylene glycol di(meth)acrylate (the number of ethoxy groups is 2 to 14), polypropylene glycol di(meth)acrylate (the number of propylene groups is 2 to 14); bisphenol A polyoxyethylene diacrylate (i.e., 2,2-bis(4-acryloxypolyethoxyphenyl)propane), bisphenol A polyoxyethylene dimethacrylate (i.e., 2,2-bis(4-methacryloxypolyethoxyphenyl)propane), bisphenol A diglycidyl ether diacrylate, bisphenol A diglycidyl ether dimethacrylate; and esterified products of polyvalent carboxylic acids (such as phthalic anhydride) and substances having a hydroxyl group and an ethylenically unsaturated group (such as β-hydroxyethyl acrylate and β-hydroxyethyl methacrylate).

As the polyfunctional monomer, in addition to the compounds above, (meth)acrylates having a skeleton derived from dipentaerythritol can be used. Examples of such (meth)acrylates include dipentaerythritol di(meth)acrylate, dipentaerythritol tri(meth)acrylate, dipentaerythritol tetra(meth)acrylate, dipentaerythritol penta(meth)acrylate, and alkylene oxide-modified compounds thereof. Among these compounds, dipentaerythritol hexa(meth)acrylate and alkylene oxide-modified dipentaerythritol hexa(meth)acrylate are preferred.

If the photopolymerizable compound as the component (B) is used in combination with the monofunctional monomer or the polyfunctional monomer other than the component (B), the compounding proportion of these monomers is not particularly limited; from the viewpoint of obtaining photo-curability and reducing corrosion of electrodes, the proportion of the photopolymerizable compound as the component (B) is preferably 30 parts by mass or more, more preferably 50 parts by mass or more, still more preferably 75 parts by mass or more in 100 parts by mass of the total amount of the photopolymerizable compounds contained in the photosensitive resin composition.

Examples of the photopolymerization initiators as the component (C) include aromatic ketones such as benzophenone, N,N,N′,N′-tetramethyl-4,4′-diaminobenzophenone (Michler's ketone), N,N,N′,N′-tetraethyl-4,4′-diaminobenzophenone, 4-methoxy-4′-dimethylaminobenzophenone, 2-benzyl-2-dimethylamino-1-(4-morpholinophenyl)-butanone-1, and 2-methyl-1-[4-(methylthio)phenyl]-2-morpholino-propanone-1; quinones such as 2-ethylanthraquinone, phenanthrenequinone, 2-tert-butylanthraquinone, octamethylanthraquinone, 1,2-benzanthraquinone, 2,3-benzanthraquinone, 2-phenylanthraquinone, 2,3-diphenylanthraquinone, 1-chloroanthraquinone, 2-methylanthraquinone, 1,4-naphthoquinone, 9,10-phenanthraquinone, 2-methyl 1,4-naphthoquinone, and 2,3-dimethylanthraquinone; benzoin ether compounds such as benzoin methyl ether, benzoin ethyl ether, benzoin phenyl ether, and benzoin compounds such as benzoin, methyl benzoin, and ethyl benzoin; oxime ester compounds such as 1,2-octanedione, 1-[4-(phenylthio)-, 2-(O-benzoyloxime)], and ethanone, 1-[9-ethyl-6-(2-methylbenzoyl)-9H-carbazole-3-yl]-, 1-(O-acetyloxime); benzyl derivatives such as benzyl dimethyl ketal; 2,4,5-triarylimidazole dimers such as 2-(o-chlorophenyl)-4,5-diphenylimidazole dimers, 2-(o-chlorophenyl)-4,5-di(methoxyphenyl)imidazole dimers, 2-(o-fluorophenyl)-4,5-diphenylimidazole dimers, 2-(o-methoxyphenyl)-4,5-diphenylimidazole dimers, and 2-(p-methoxyphenyl)-4,5-diphenylimidazole dimers; acridine derivatives such as 9-phenylacridine and 1,7-bis(9,9′-acridinyl)heptane; N-phenylglycine, N-phenylglycine derivatives, coumarin compounds, and oxazole compounds.

Among these, oxime ester compounds and/or phosphine oxide compounds are preferred because of the transparency of the protective film to be formed and pattern formability at a film thickness of 10 μm or less. Examples of the oxime ester compounds include compounds represented by the following formulae (C-1) and (C-2); from the viewpoint of fast curing properties and transparency, compounds represented by the following formula (C-1) are preferred:

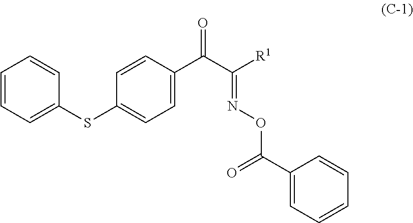

where R¹ represents an alkyl group having 1 to 12 carbon atoms, an organic group including a cycloalkyl group having 3 to 20 carbon atoms, an alkanoyl group having 2 to 12 carbon atoms, an alkenoyl group having 4 to 6 carbon atoms and having a double bond not conjugated with a carbonyl group, a benzoyl group, or an alkoxycarbonyl group having 2 to 6 carbon atoms or a phenoxycarbonyl group. An aromatic ring in the above formula (C-1) may have a substituent as long as the advantageous effects of the present invention are not inhibited.

In the above formula (C-1), R¹ is preferably an alkyl group having 1 to 12 carbon atoms or an organic group including a cycloalkyl group having 3 to 20 carbon atoms, more preferably an alkyl group having 3 to 10 carbon atoms or an organic group including a cycloalkyl group having 4 to 15 carbon atoms, particularly preferably an alkyl group having 4 to 8 carbon atoms or an organic group including a cycloalkyl group having 4 to 10 carbon atoms.

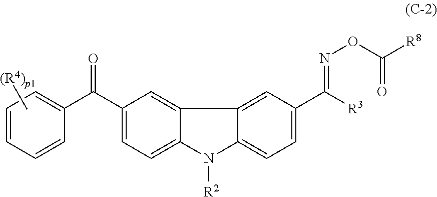

where R² represents a halogen atom, an alkyl group having 1 to 12 carbon atoms, a cyclopentyl group, a cyclohexyl group, a phenyl group, a benzyl group, a benzoyl group, an alkanoyl group having 2 to 12 carbon atoms, an alkoxycarbonyl group having 2 to 12 carbon atoms, or a phenoxycarbonyl group; R³ represents an alkyl group having 1 to 12 carbon atoms or an organic group including a cycloalkyl group having 3 to 20 carbon atoms; R⁴ each independently represents a halogen atom, an alkyl group having 1 to 12 carbon atoms, a cyclopentyl group, a cyclohexyl group, a phenyl group, a benzyl group, a benzoyl group, an alkanoyl group having 2 to 12 carbon atoms, an alkoxycarbonyl group having 2 to 12 carbon atoms, or a phenoxycarbonyl group; R⁵ represents an alkyl group or an arylene group having 2 to 20 carbon atoms; and p1 represents an integer of 0 to 3; if p1 is 2 or more, a plurality of R⁴ present may be the same or different. Carbazole may have a substituent in the range not inhibiting the advantageous effects of the present invention.

In the above formula (C-2), R² is preferably an alkyl group having 1 to 12 carbon atoms, more preferably an alkyl group having 1 to 8 carbon atoms, particularly preferably an alkyl group having 1 to 4 carbon atoms.

In the above formula (C-2), R³ is preferably an alkyl group having 1 to 8 carbon atoms or an organic group including a cycloalkyl group having 4 to 15 carbon atoms, more preferably an alkyl group having 1 to 4 carbon atoms or a cycloalkyl group having 4 to 10 carbon atoms.

Examples of the compound represented by the above formula (C-1) and the compound represented by the formula (C-2) include 1,2-octanedione, 1-[4-(phenylthio)-, 2-(O-benzoyloxime)] and ethanone, 1-[9-ethyl-6-(2-methylbenzoyl)-9H-carbazole-3-yl]-, 1-(O-acetyloxime). 1,2-Octanedione, 1-[4-(phenylthio)-, 2-(O-benzoyloxime)] is commercially available as IRGACURE-OXE01 (manufactured by BASF SE, trade name), and ethanone, 1-[9-ethyl-6-(2-methylbenzoyl)-9H-carbazole-3-yl]-, 1-(O-acetyloxime) as IRGACURE-OXE02 (manufactured by Ciba Specialty Chemicals Inc., trade name). These are used singly or in combinations of two or more.

Among these compounds represented by the above formula (C-1), particularly 1,2-octanedione, 1-[4-(phenylthio)-, 2-(O-benzoyloxime)] is extremely preferred.

Examples of the phosphine oxide compounds include compounds represented by the following formulae (C-3) and (C-4). From the viewpoint of fast curing properties and transparency, a compound represented by the following formula (C-3) is preferred:

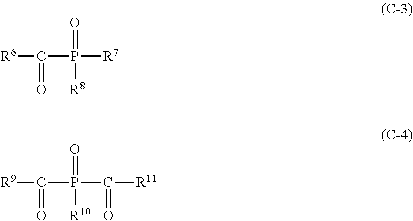

where R⁶, R⁷, and R⁸ each independently represent an alkyl group or an aryl group having 1 to 20 carbon atoms; R⁹, R¹⁰, and R¹¹ each independently represent an alkyl group or an aryl group having 1 to 20 carbon atoms.

If R⁶, R⁷, or R⁸ in the above formula (C-3) is an alkyl group having 1 to 20 carbon atoms, the alkyl group may be linear, branched, or cyclic; it is more preferred that the alkyl group have 5 to 10 carbon atoms. If R⁹, R¹⁰, or R¹¹ in the above formula (C-4) is an alkyl group having 1 to 20 carbon atoms, the alkyl group may be linear, branched, or cyclic; it is more preferred that the alkyl group have 5 to 10 carbon atoms.

If R⁶, R⁷, or R⁸ in the above formula (C-3) is an aryl group, the aryl group may have a substituent. Examples of the substituent include an alkyl group having 1 to 6 carbon atoms and an alkoxy group having 1 to 4 carbon atoms. If R⁹, R¹⁰, or R¹¹ in the above formula (C-4) is an aryl group, the aryl group may have a substituent. Examples of the substituent include an alkyl group having 1 to 6 carbon atoms and an alkoxy group having 1 to 4 carbon atoms.

Among these, in the above formula (C-3), R⁶, R⁷, and R⁸ are preferably an aryl group; in the compound represented by the formula (C-4), R⁹, R¹⁰, and R¹¹ are preferably an aryl group.

As the compound represented by the above formula (C-3), 2,4,6-trimethylbenzoyl-diphenyl-phosphine oxide is preferred because of the transparency of the cured film to be formed and the pattern formability at a film thickness of 10 μm or less. 2,4,6-Trimethylbenzoyl-diphenyl-phosphine oxide is commercially available as DAROCUR-TPO (manufactured by BASF Japan Ltd., trade name), for example.

The content of the photopolymerization initiator as the component (C) is preferably 0.1 to 20 parts by mass, more preferably 0.5 to 10 parts by mass, still more preferably 1.0 to 3 parts by mass relative to 100 parts by mass of the total amount of the component (A) and the component (B).

At a content of the component (C) within this range, photosensitivity is sufficient, and problems such as insufficient photo-curing of the inside caused by an increase in absorption of light on the surface of the composition during exposure to the light and a reduction in visible light transmittance can be prevented.

It is preferred that the photosensitive resin composition according to the present embodiment further contain at least one compound (hereinafter also referred to as component (D)) selected from the group consisting of triazole compounds, thiadiazole compounds, and tetrazole compounds in view of compatibility between anti-corrosive properties and developability.

Examples of the triazole compounds include triazole compounds including a mercapto group such as benzotriazole, 1H-benzotriazole-1-acetonitrile, benzotriazole-5-carboxylic acid, 1H-benzotriazole-1-methanol, carboxybenzotriazole, and 3-mercaptotriazole; and triazole compounds including an amino group such as 3-amino-5-mercaptotriazole.

Examples of the thiadiazole compounds include 2-amino-5-mercapto-1,3,4-thiadiazole and 2,1,3-benzothiadiazole.

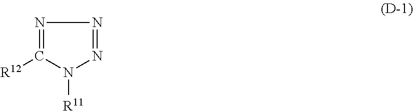

where R¹¹ and R¹² each independently represent hydrogen, an alkyl group having 1 to 20 carbon atoms, a cycloalkyl group having 3 to 10 carbon atoms, a phenyl group, an aminophenyl group, an alkylphenyl group having 7 to 20 carbon atoms, an amino group, a mercapto group, an alkylmercapto group having 1 to 10 carbon atoms, or a carboxyalkyl group having 2 to 10 carbon atoms.

Examples of the alkyl group include a methyl group, an ethyl group, a propyl group, an iso-propyl group, a butyl group, a sec-butyl group, a tert-butyl group, a pentyl group, a hexyl group, a heptyl group, an octyl group, a nonyl group, a decyl group, an undecyl group, a tridecyl group, a tetradecyl group, a pentadecyl group, an octadecyl group, a nonadecyl group, and an icosyl group.

Examples of the cycloalkyl group include a cyclopentyl group, a cyclohexyl group, and a cyclooctyl group; examples of the alkylphenyl group include a methyl phenyl group and an ethyl phenyl group.

Examples of the alkylmercapto group include a methylmercapto group and an ethylmercapto group; examples of the carboxyalkyl group include a carboxymethyl group and a carboxyethyl group.

Specific examples of the tetrazole compound represented by the above formula (D-1) include 1H-tetrazole, 5-amino-1H-tetrazole, 5-methyl-1H-tetrazole, 1-methyl-5-ethyl-tetrazole, 1-methyl-5-mercapto-tetrazole, 5-(2-aminophenyl)-1H-tetrazole, 1-cyclohexyl-5-mercapto-tetrazole, 1-phenyl-5-mercapto-tetrazole, 1-carboxymethyl-5-mercapto-tetrazole, 5-phenyl-1H-tetrazole, and 1-phenyl-tetrazole.

The tetrazole compound represented by the above formula (D-1) is suitably a water-soluble salt thereof. Specific examples thereof include alkali metal (such as sodium, potassium, and lithium) salts of 1-carboxymethyl-5-mercapto-tetrazole.

Among these, 1H-tetrazole, 5-amino-1H-tetrazole, and 1-methyl-5-mercapto-1H-tetrazole are particularly preferred from the viewpoint of a reduction in corrosion of electrodes, adhesion to metal electrodes, readiness in development, and transparency.

These tetrazole compounds and water-soluble salts thereof may be used singly or in combinations of two or more.

From the viewpoint of further enhancement in the developability if the surface of the electrode on which the cured film is disposed has a metal such as copper, silver, or nickel, it is preferred that the photosensitive resin composition further contain a tetrazole compound having an amino group. In this case, a developing residue can be reduced, readily forming a protective film with a good pattern. It is believed that this is because compounding of a tetrazole compound having an amino group attains a good balance between solubility in the developing solution and adhesion property to the metal.

If the photosensitive resin composition contains a tetrazole compound having an amino group, the above effects are attained; thus, the photosensitive resin composition and the photosensitive element according to the present embodiment are suitable in formation of a protective film for protecting electrodes in the frame region of the touch panel having a metal layer formed of copper to enhance the conductivity, for example.

The content of the component (D) in the photosensitive resin composition according to the present embodiment is preferably 0.05 to 10.0 parts by mass, more preferably 0.1 to 2.0 parts by mass, still more preferably, 0.2 to 1.0 parts by mass relative to 100 parts by mass of the total amount of the component (A) and the component (B).

At a content of the component (D) within this range, problems such as a reduction in developability or resolution are prevented, and effects of enhancing a reduction in corrosion of electrodes and adhesion to metal electrodes can be sufficiently attained.

The photosensitive resin composition according to the present embodiment can contain an adhesion imparting agent such as a silane coupling agent, a leveling agent, a plasticizer, a filler, an antifoaming agent, a flame retardant, a stabilizer, an antioxidant, a fragrance, a thermal crosslinking agent, a polymerization inhibitor, and the like each in an amount of about 0.01 to 20 parts by mass relative to 100 parts by mass of the total amount of the component (A) and the component (B), when necessary. These can be used singly or in combinations of two or more.

From the viewpoint of an enhancement in the anti-corrosive properties of the cured film to be formed, it is preferred that the hydroxyl value of the total solid content be 40 mgKOH/g or less in the photosensitive resin composition according to the present embodiment.

The hydroxyl value of the total solid content in the photosensitive resin composition can be measured as follows. Namely, first, 1 g of the photosensitive resin composition whose hydroxyl value is to be measured is precisely weighed. If the photosensitive resin composition contains a volatile component such as a synthetic solvent or a diluted solvent, the photosensitive resin composition is preheated at a temperature about 10° C. higher than the boiling point of the volatile component for 1 to 4 hours to remove the volatile component. 10 mL of a solution of 10% by mass pyridine acetate, anhydrous is added to the photosensitive resin composition precisely weighed to be uniformly dissolved, and is heated at 100° C. for 1 hour. After heating, 10 mL of water and 10 mL of pyridine are added, and the solution is heated at 100° C. for 10 minutes. Subsequently, the solution is subjected to neutralization titration with a solution of 0.5 mol/L potassium hydroxide in ethanol using an automatic titrator (manufactured by Hiranuma Sangyo Co., Ltd., “COM-1700”) to measure the hydroxyl value. The hydroxyl value can be calculated from the following expression:

hydroxyl value=(A−B)×f×56.11×0.5/sample (g)+acid value

where A represents an amount (mL) of the solution of 0.5 mol/L potassium hydroxide in ethanol used in the blank test; B represents an amount (mL) of the solution of 0.5 mol/L potassium hydroxide in ethanol used in titration; and f represents a factor.

In the photosensitive resin composition according to the present embodiment, it is preferred from the viewpoint of an enhancement in the anti-corrosive properties of the cured film to be cured that the hydroxyl value of the component (A) be 50 mgKOH/g or less.

The hydroxyl value of the component (A) can be determined by precisely weighing 1 g of the binder polymer whose hydroxyl value is to be measured, and then measuring the hydroxyl value of the binder polymer in the same manner as in the measurement of that described above. If the binder polymer contains a volatile component such as a synthetic solvent or a diluted solvent, the binder polymer is preheated at a temperature about 10° C. higher than the boiling point of the volatile component for 1 to 4 hours to remove the volatile component.

Furthermore, in the photosensitive resin composition according to the present embodiment, it is preferred from the viewpoint of an enhancement in the anti-corrosive properties of the cured film to be cured that the hydroxyl value of the component (B) be 90 mgKOH/g or less.

The hydroxyl value of the component (B) can be determined by precisely weighing 1 g of the photopolymerizable compound whose hydroxyl value is to be measured, and then measuring the hydroxyl value of the photopolymerizable compound in the same manner as in the measurement of that described above. If the photopolymerizable compound contains a volatile component such as a synthetic solvent or a diluted solvent, the photopolymerizable compound is preheated at a temperature about 10° C. higher than the boiling point of the volatile component for 1 to 4 hours to remove the volatile component.

In the photosensitive resin composition according to the present embodiment, the minimum value of the visible light ray transmittance is preferably 90% or more, more preferably 92% or more, still more preferably 95% or more.

Here, the visible light ray transmittance of the photosensitive resin composition is determined as follows. First, the photosensitive resin composition is applied onto a support film in a dry thickness of 10 μm or less, and is dried to form a photosensitive resin composition layer (photosensitive layer). Next, the photosensitive resin composition layer is laminated on a glass substrate with a laminator. A sample for measurement having the photosensitive resin composition layer and the support film laminated on the glass substrate is thereby obtained. Next, the obtained sample for measurement is irradiated with ultraviolet light to photo-cure the photosensitive resin composition layer, and the transmittance in a wavelength band of 400 to 700 nm for measurement is then measured with a UV-visible spectrophotometer.

If the minimum value of the transmittance of the light in the wavelength band of 400 to 700 nm, which is typical light in the visible light wavelength band, is 90% or more, and for example, the transparent electrode of the display unit in the touch panel (touch sensor) is also protected, and the cured film is seen from the end of the display unit in protection of the metal layer in the frame region of the touch panel (touch sensor) (for example, a layer having a copper layer formed on an ITO electrode), a reduction in the display quality, the color, or the luminance of the display unit can be sufficiently prevented.

From the viewpoint of further enhancement in the visibility of the touch panel, in the photosensitive resin composition according to the present embodiment, the b* of the CIELAB color system is preferably −0.2 to 1.0, more preferably −0.0 to 0.7, still more preferably 0.1 to 0.4. At b* of 0.8 or more or −0.2 or less, the display quality and the color in the display unit tend to be reduced as in the cases at a visible light ray transmittance of less than 90%. The b* of the CIELAB color system is measured, for example, using a spectrocolorimeter “CM-5” manufactured by KONICA MINOLTA, INC.; a photosensitive resin composition layer having a thickness of 5 μm is formed on a glass substrate having a thickness of 0.7 mm and b* of 0.1 to 0.2, is irradiated with ultraviolet light to photo-cure the photosensitive resin composition layer, and the b* is then measured with a D65 light source set at a viewing angle of 2° to obtain the b*.

It is preferred that the photosensitive resin composition according to the present embodiment be formed into a photosensitive film as the photosensitive element according to the present embodiment and used. If the photosensitive film is laminated on the transparent base material, this can greatly contribute to a reduction in the manufacturing process and a reduction in cost, for example, can easily implement the roll-to-roll process or can reduce a solvent drying step.

The photosensitive layer 20 can be formed by preparing the photosensitive resin composition according to the present embodiment as a coating solution, applying the coating solution onto a support film, and drying the coating. The coating solution can be obtained by uniformly dissolving or dispersing the components forming the photosensitive resin composition according to the present embodiment in a solvent.

The solvent is not particularly limited, and known solvents can be used; examples thereof include acetone, methyl ethyl ketone, methyl isobutyl ketone, toluene, methanol, ethanol, propanol, butanol, methylene glycol, ethylene glycol, propylene glycol, ethylene glycol monomethyl ether, ethylene glycol monoethyl ether, propylene glycol monomethyl ether, chloroform, and methylene chloride. These solvents may be used singly or in combination in the form of a mixed solvent.

Examples of the coating method include doctor blade coating, Meyer bar coating, roll coating, screen coating, spin coating, inkjet coating, spray coating, dip coating, gravure coating, curtain coating, and die coating.

The drying condition is not particularly limited; the drying temperature is preferably 60 to 130° C., and the drying time is preferably 0.5 to 30 minutes.

For the thickness of the photosensitive layer, the dry thickness is preferably 10 μm or less, more preferably 2 to 10 μm, still more preferably 3 to 8 μm such that a sufficient effect is demonstrated in protection of the electrodes and the difference in level on the surface of the touch panel (touch sensor) caused by the electrode protective film partially formed is minimized.

In the present embodiment, the photosensitive layer 20 has a visible light ray transmittance of preferably 90% or more, more preferably 92% or more, still more preferably 95% or more. It is preferred that the photosensitive layer 20 be adjusted to have b* of −0.2 to 1.0 in the CIELAB color system.

The viscosity at 30° C. of the photosensitive layer 20 is preferably 15 to 100 MPa·s, more preferably 20 to 90 MPa·s, still more preferably 25 to 80 MPa·s to prevent elution of the photosensitive resin composition from end surfaces of the photosensitive element for 1 month or longer and prevent exposure deficits, undevelopment, and the like caused by fragments of the photosensitive resin composition adhering to the substrate during cutting of the photosensitive element if the photosensitive layer 20 is used as a roll-like photosensitive element for forming a cured film to form a cured film on a transparent base material.

The viscosity is a value obtained as follows: a circular film formed from the photosensitive resin composition and having a diameter of 7 mm and a thickness of 2 mm is used as a sample for measurement, and the rate of change in the thickness is measured when a load of 1.96×10⁻² N is applied in the thickness direction of the sample at 30° C. and 80° C., and the Newtonian fluid is assumed from this rate of change and is converted into the viscosity.

Examples of the protection film 30 (cover film) include films made of polyethylene, polypropylene, poly(ethylene terephthalate), polycarbonate, and polyethylene-vinyl acetate copolymer, and laminate films composed of polyethylene-vinyl acetate copolymer and polyethylene and having a thickness of about 5 to 100 μm.

The photosensitive element 1 can be wound into a roll for storage or use.

In the present invention, the coating solution of the photosensitive resin composition according to the present embodiment may be applied onto the transparent base material, and be dried to dispose a photosensitive layer composed of the photosensitive resin composition. Also in this application, it is preferred that the photosensitive layer satisfy the conditions on the film thickness, the visible light ray transmittance, and the b* in the CIELAB color system.

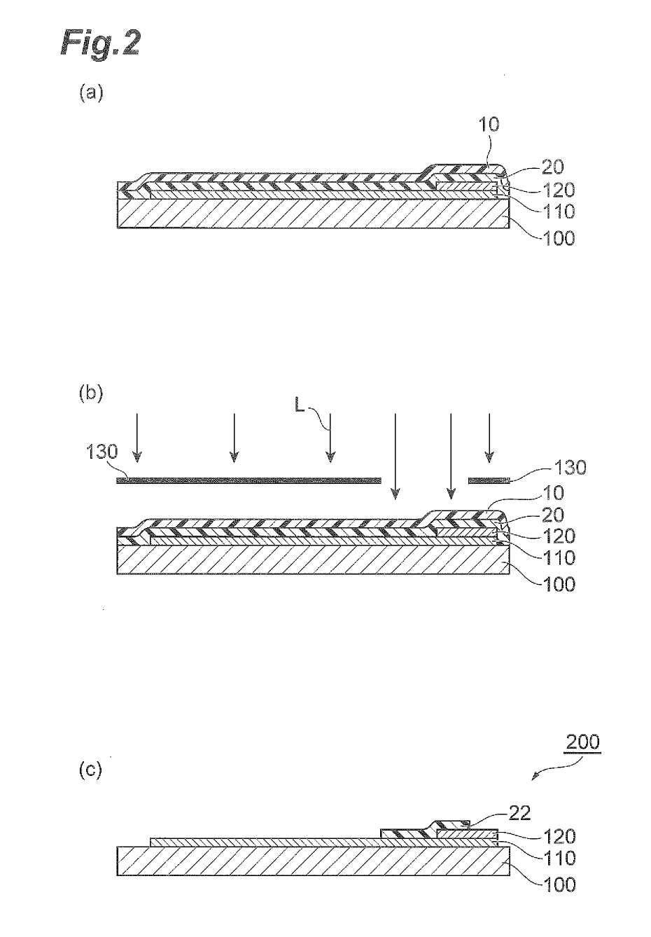

Next, the method of manufacturing a transparent base material provided with a cured film according to the present invention will be described. As the method of manufacturing a transparent base material provided with a cured film according to one embodiment of the present invention, a method of manufacturing a base material for touch panels provided with a protective film will be described. FIG. 2 is a schematic sectional view for describing one embodiment of the method of manufacturing a base material for touch panels provided with a protective film according to the present invention.

The method of manufacturing a base material for touch panels provided with a protective film according to the present embodiment comprises a first step of disposing a photosensitive layer 20 composed of the photosensitive resin composition according to the present embodiment on a transparent base material (base material for touch panels) 100 having electrodes 110 and 120 for a touch panel (see FIG. 2(a)); a second step of curing a predetermined portion of the photosensitive layer 20 through irradiation with active light rays (see FIG. 2(b)); and a third step of removing the photosensitive layer other than the predetermined portion after exposure to form a protective film 22 composed of a cured product of the photosensitive resin composition, the film coating part or all of the electrodes (see FIG. 2(c)). The base material for touch panels provided with a protective film is thereby obtained. The resulting base material for touch panels provided with a protective film can be used as a touch panel (touch sensor) 200 provided with a protective film.

The base material for touch panels used in the present embodiment is not particularly limited; examples thereof include substrates usually used for touch panels (touch sensors) such as glass plates, plastic plates, and ceramic plates. The electrodes for a touch panel are disposed on this substrate. Examples of the electrodes include electrodes made of ITO, Cu, Al, Mo, and Ag and TFT. An insulation layer may be disposed on the substrate. The base material for touch panels preferably has a minimum light transmittance of 85% or more in a wavelength band of 400 to 700 nm.

The base material for touch panels having electrodes for a touch panel 110 and 120 illustrated in FIG. 2 can be obtained by the following procedure, for example. After a metal film is formed on a transparent base material such as a PET film by depositing ITO and Cu in this order by sputtering, a photosensitive film for etching is applied to the metal film to form a desired resist pattern; unnecessary Cu is removed with an etching solution such as an iron chloride aqueous solution, and the resist pattern is then removed by peeling.

In the first step of the present embodiment, after a protection film 30 of a photosensitive element 1 according to the present embodiment is removed, the photosensitive layer 20 is press bonded with heating of the photosensitive element to the surface of the base material for touch panels having the electrodes for a touch panel 110 and 120 disposed thereon to laminate the layer (see FIG. 2(a)).

Examples of press bonding means include press bonding rolls. The press bonding roll may include heating means so as to enable heat press bonding.

The heating temperature in heat press bonding is preferably 10 to 180° C., more preferably 20 to 160° C., still more preferably 30 to 150° C. so as to sufficiently ensure the adhesion between the photosensitive layer and the base material for touch panels and barely cause thermal curing or thermal decomposition of the constitutional components of the photosensitive layer.

The press bonding pressure during heat press bonding or the line pressure is preferably 50 to 1×10⁵ N/m, more preferably 2.5×10² to 5×10⁴ N/m, still more preferably 5×10² to 4×10⁴ N/m from the viewpoint of sufficiently ensuring the adhesion between the photosensitive layer and the base material for touch panels and preventing deformation of the base material for touch panels.

If the photosensitive element 1 is heated as above, the base material does not need to be subjected to a pre-heat treatment; it is preferred that the base material be subjected to a pre-heat treatment to further enhance the adhesion between the photosensitive layer and the base material. The pre-heating temperature at this time is preferably 30 to 180° C.

In the present embodiment, instead of use of the photosensitive element, the photosensitive resin composition according to the present embodiment can be prepared as a coating solution, and the coating solution is applied to the surface of the base material for touch panels having the electrodes 110 and 120 for a touch panel disposed thereon, and be dried to form the photosensitive layer 20.

It is preferred that the photosensitive layer 20 satisfy the conditions on the film thickness, the visible light ray transmittance, and the b* in the CIELAB color system.

In the second step of the present embodiment, the photosensitive layer 20 is exposed through a photomask 130 to active light rays L into a pattern (see FIG. 2(b)).

In exposure, if the support film 10 on the photosensitive layer 20 is transparent, the photosensitive layer 20 can be exposed as it is; if the support film 10 is opaque, the support film is removed, and then the photosensitive layer 20 is exposed. In view of protection of the photosensitive layer, it is preferred that a transparent polymer film be used as a support film, and the photosensitive layer 20 be exposed through the polymer film while the polymer film remains.

As a light source for the active light rays used in exposure, known active light sources can be used; examples thereof include carbon arc lamps, super-high pressure mercury lamps, high pressure mercury lamps, and xenon lamps, and the light source is not particularly limited as long as those effectively radiate ultraviolet light.

The irradiation intensity of the active light rays at this time is usually 1×10² to 1×10⁴ J/m²; heating can be performed during irradiation. If the irradiation intensity of the active light rays is less than 1×10² J/m², the photo-curing effect tends to be insufficient; if the irradiation intensity of the active light rays is more than 1×10⁴ J/m², the color of the photosensitive layer tends to change.

In the third step of the present embodiment, the photosensitive layer after exposure is developed with a developing solution to remove unexposed portions (namely, portions of the photosensitive layer other than the predetermined portion), thereby forming a protective film 22 composed of a cured product of the photosensitive resin composition according to the present embodiment, and having a thickness of 10 μm or less to coat part or all of the base material. The formed protective film 22 can have a predetermined pattern.

If the support film is laminated on the photosensitive layer, the support film is removed after exposure, and development is then performed with a developing solution to remove unexposed portions.

Examples of the developing method include methods of performing development with a known developing solution such as an alkali aqueous solution, an aqueous developing solution, or an organic solvent by a known method such as spraying, showering, shaking immersion, brushing, or scrapping to remove unnecessary portions; among these, use of an alkali aqueous solution is preferred in the environmental and safety viewpoints.

Examples of the bases of the alkali aqueous solutions include alkali hydroxides (such as hydroxides of lithium, sodium, or potassium), alkali carbonates (carbonates or bicarbonates of lithium, sodium, or potassium), alkali metal phosphates (such as potassium phosphate and sodium phosphate), alkali metal pyrophosphates (such as sodium pyrophosphate and potassium pyrophosphate), tetramethylammonium hydroxide, and triethanolamine; among these, tetramethylammonium hydroxide is preferred.

An aqueous solution of sodium carbonate is preferably used, and for example, a diluted solution of sodium carbonate at 20 to 50° C. (0.5 to 5% by weight aqueous solution) is suitably used.

The developing temperature and time can be adjusted according to the developability of the photosensitive resin composition according to the present embodiment.

The alkali aqueous solution can be mixed with a surfactant, an antifoaming agent, and a small amount of an organic solvent to promote development, for example.

After development, the base of the alkali aqueous solution remaining on the photosensitive layer after photo-curing can be subjected to an acid treatment (neutralization treatment) with an organic acid, inorganic acid, or an acid aqueous solution thereof by a known method such as spraying, shaking immersion, brushing, or scrapping.

In addition, after the acid treatment (neutralization treatment), a step of washing with water can also be performed.

After development, when necessary, the cured product may be further cured by exposure (for example, 5×10³ to 2×10⁴ J/m²). While the photosensitive resin composition according to the present embodiment exhibits high adhesion to metal without a heating step after development, when necessary, a heat treatment (80 to 250° C.) may be performed instead of or in combination with exposure after development.

As described above, the photosensitive resin composition according to the present embodiment and photosensitive element is suitably used to form a cured film on a transparent base material and to form a protective film on a base material for touch panels, for example. The photosensitive resin composition can be used with a solvent in the form of a mixed coating solution to form a protective film.

Moreover, the present invention can provide a material for forming a protective film comprising the photosensitive resin composition according to the present invention. The material for forming a protective film can comprise the photosensitive resin composition according to the present embodiment described above; and it is preferred that the material be the coating solution containing a solvent described above.

(Electrical Component and Manufacturing Method Thereof)

The electrical component according to the present embodiment comprises the transparent base material provided with a cured film according to the present embodiment. The transparent base material provided with a cured film includes a cured product (such as a cured film) of the photosensitive resin composition according to the present embodiment on the transparent base material. In the electrical component according to the present embodiment, the cured film can be used as a protective member (such as a protective film) or an insulation member (such as an insulation film), for example.

Examples of the electrical component according to the present embodiment include touch panels, liquid crystal displays, organic electroluminescent displays, solar cell modules, printed circuit boards, and electronic paper.

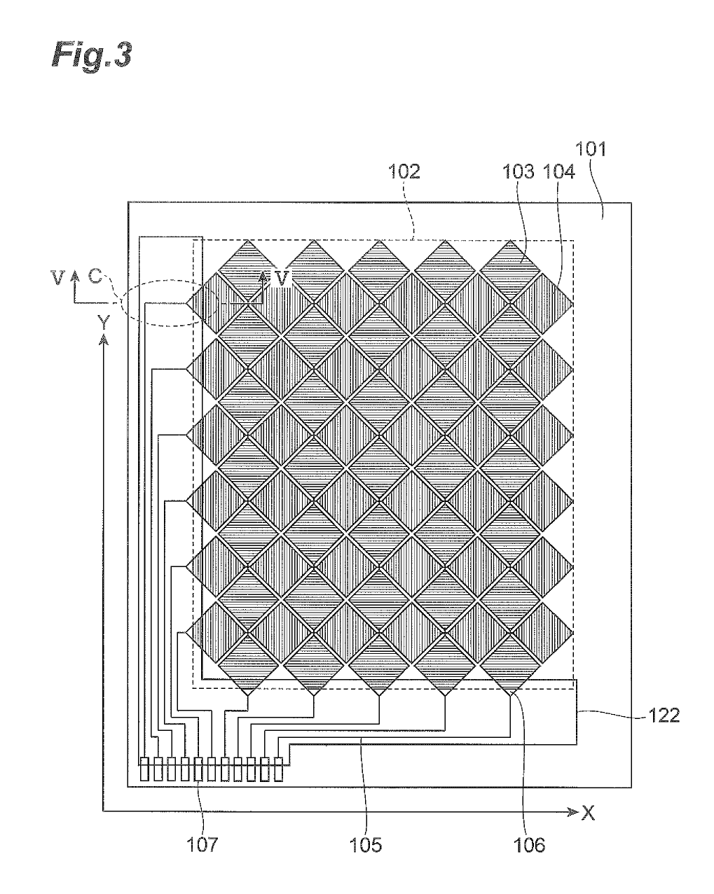

Next, one example of use site of a cured film according to the present invention (such as a protective film) will be described using FIG. 3 to FIG. 5. FIG. 3 is a schematic top view illustrating one example of a capacitive touch panel. In the touch panel illustrated in FIG. 3, a touch screen 102 for detecting the coordinate of the touch location is disposed on one surface of a transparent substrate 101, and transparent electrodes 103 and transparent electrodes 104 for detecting a change in capacitance in this region are disposed on the transparent substrate 101. The transparent electrodes 103 and the transparent electrodes 104 detect a change in capacitance of the touch location as the coordinate of the X location and the coordinate of the Y location.

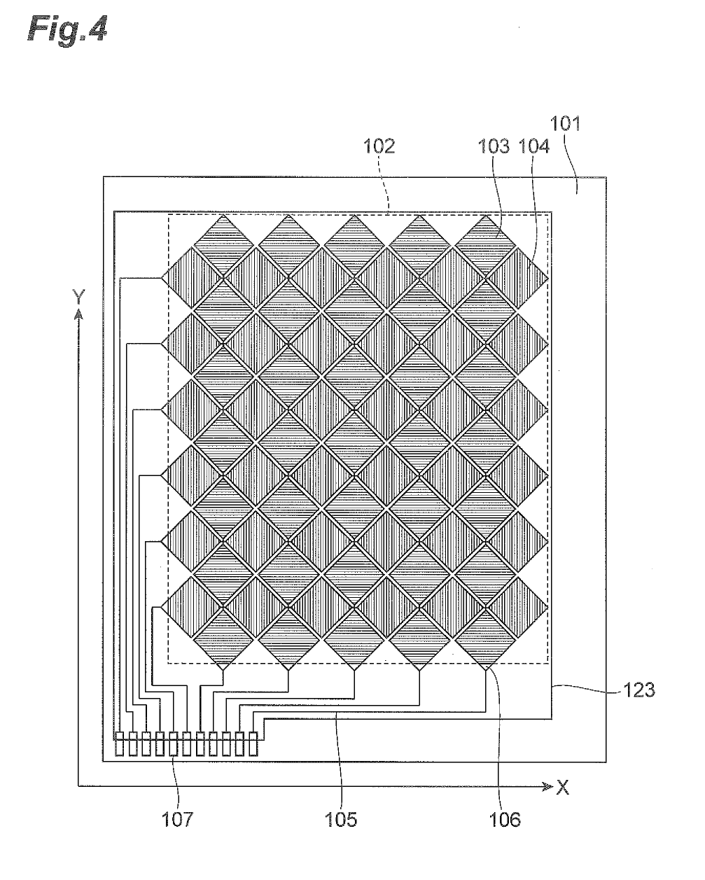

On the transparent substrate 101, drawing wirings 105 for transmitting detected signals for the touch location from the transparent electrodes 103 and the transparent electrodes 104 to an external circuit are disposed. The drawing wirings 105 are connected to the transparent electrodes 103 and the transparent electrodes 104 through connection electrodes 106 disposed on the transparent electrodes 103 and the transparent electrodes 104. Connection terminals 107 to the external circuit are disposed on the ends of the drawing wirings 105 opposite to the connection portions thereof to the transparent electrodes 103 and the transparent electrodes 104. The photosensitive resin composition according to the present invention can be suitably used to form a resin cured film pattern as a protective film 122 for the drawing wirings 105, the connection electrodes 106, and the connection terminals 107. At this time, electrodes on the sensing region can also be protected at the same time. In FIG. 3, while the protective film 122 protects the drawing wirings 105, the connection electrodes 106, part of the electrodes in the sensing region, and part of the connection terminals 107, the place where the protective film is disposed may be appropriately varied. For example, as illustrated in FIG. 4, a protective film 123 may be disposed so as to completely protect the touch screen 102.

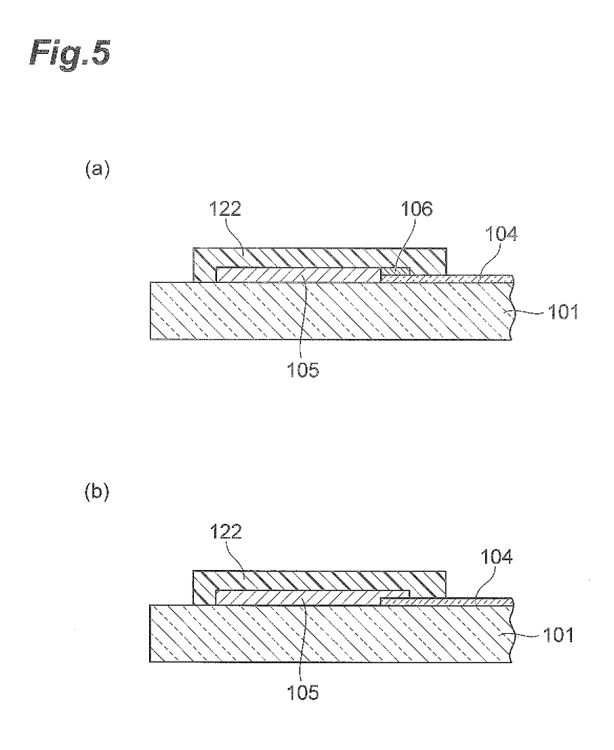

Using FIG. 5, the structure of the cross section of the connection portion between the transparent electrode and the drawing wiring in the touch panel illustrated in FIG. 3 will be described. FIG. 5 is a partial sectional view of a portion C taken along line V-V shown in FIG. 3 and a drawing for describing the connection portion between the transparent electrode 104 and the drawing wiring 105. As illustrated in FIG. 5(a), the transparent electrode 104 and the drawing wiring 105 are electrically connected to each other through the connection electrode 106. As illustrated in FIG. 5(a), part of the transparent electrode 104 and all of the drawing wiring 105 and the connection electrode 106 are covered with the resin cured film pattern as the protective film 122. Similarly, the transparent electrode 103 and the drawing wiring 105 are directly connected to each other, and are electrically connected to each other through the connection electrode 106. As illustrated in FIG. 5(b), the transparent electrode 104 and the drawing wiring 105 may be electrically connected to each other directly but not through the connection electrode 106. The photosensitive resin composition and the photosensitive element according to the present invention are suitably used for formation of the resin cured film pattern as the protective film in the structural component.

The method of manufacturing a touch panel in the present embodiment will be described. First, transparent electrodes (coordinates of X position) 103 are formed on a transparent substrate 101 as the base material for touch panels. Subsequently, transparent electrodes (coordinates of Y position) 104 are formed with an insulation layer (not illustrated) interposed. Formation of the transparent electrodes 103 and the transparent electrodes 104 can be performed using a method of etching the transparent electrode layer formed on the transparent substrate 101, for example.

Next, drawing wirings 105 for connecting to an external circuit, and connection electrodes 106 for connecting the drawing wirings to the transparent electrodes 103 and the transparent electrodes 104 are formed on the surface of the transparent substrate 101. The drawing wirings 105 and the connection electrodes 106 may be formed after formation of the transparent electrodes 103 and the transparent electrodes 104 or simultaneously with formation of the respective transparent electrodes. Formation of the drawing wirings 105 and the connection electrodes 106 can be performed using metal sputtering, and then etching, for example. The drawing wirings 105 can be formed, for example, using a conductive paste material containing flake silver simultaneously with formation of the connection electrodes 106 by screen printing. Next, the connection terminals 107 for connecting the drawing wirings 105 to the external circuit are formed.

The photosensitive element 1 according to the present embodiment is press bonded so as to cover the transparent electrodes 103 and the transparent electrodes 104, the drawing wirings 105, the connection electrodes 106, and the connection terminals 107 formed through the steps above, thereby disposing a photosensitive layer 20 on the electrodes. Next, the transferred photosensitive layer 20 is irradiated through a photomask with active light rays L into a pattern of a desired shape. After irradiation with the active light rays L, development is performed to remove portions of the photosensitive layer 20 other than the predetermined portion, forming a protective film 122 composed of a cured product of the predetermined portion of the photosensitive layer 20. Thus, a touch panel including the protective film 122, namely a touch panel including a base material for touch panels provided with the protective film 122 (transparent substrate 101) can be manufactured.

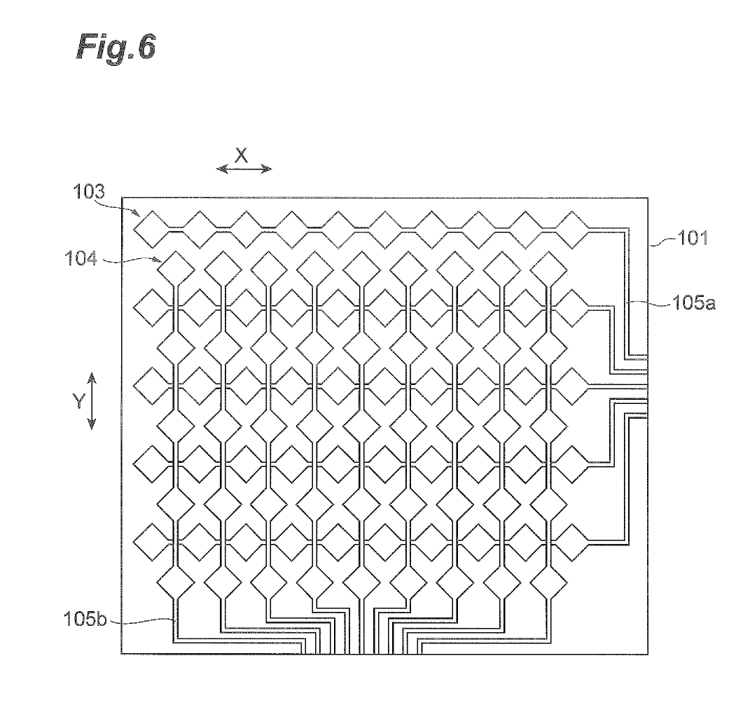

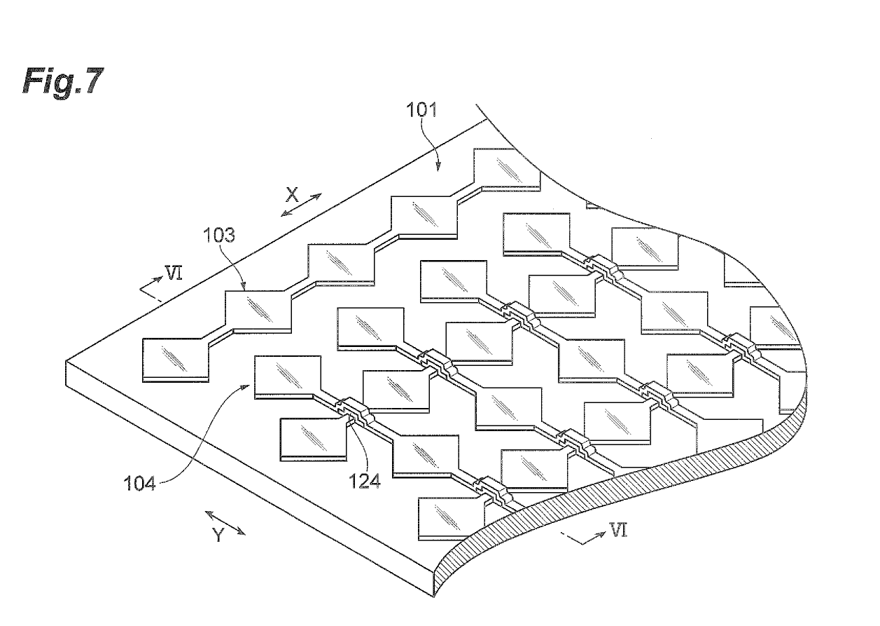

Next, as another embodiment of the electrical component and the manufacturing method thereof, one example of a capacitive touch panel having transparent electrodes present on the same plane and the manufacturing method thereof will be described using FIG. 6 to FIG. 10. The cured film according to the present invention can also be suitably used as an insulation film 124 in FIG. 7 to FIG. 10, for example.

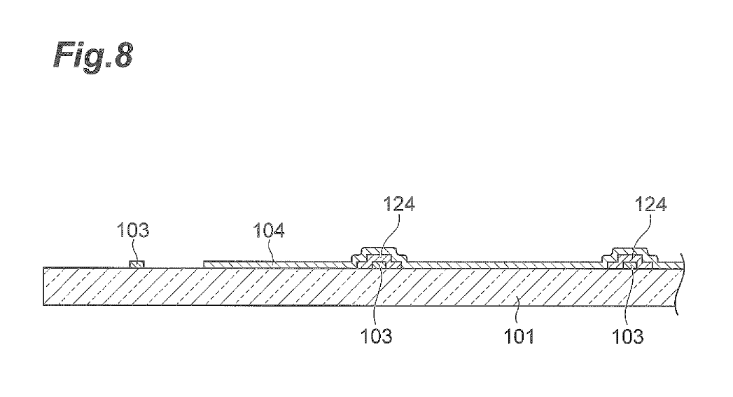

FIG. 6 is a plan view illustrating one example of a capacitive touch panel in which transparent electrodes (coordinates of X position) 103 and transparent electrodes (coordinates of Y position) 104 are present on the same plane, and FIG. 7 is a partially cutout perspective view thereof. FIG. 8 is a partial sectional view taken along line VI-VI in FIG. 7. The capacitive touch panel has the transparent electrodes 103 detecting a change in capacitance as a coordinate of X position and the transparent electrodes 104 detecting a change in capacitance as a coordinate of Y position on a transparent substrate 101. The transparent electrodes 103 and 104 detecting as the coordinate of X position and the coordinate of Y position, respectively, have drawing wirings 105a and 105b for connecting to a control circuit of a driver element circuit (not illustrated) controlling electric signals as a touch panel.

The insulation film 124 is disposed on the portion in which the transparent electrodes (coordinates of X position) 103 intersect the transparent electrodes (coordinates of Y position) 104.

A method of manufacturing a capacitive touch panel in which the transparent electrodes (coordinates of X position) 103 and the transparent electrodes (coordinates of Y position) 104 are present on the same plane will be described.

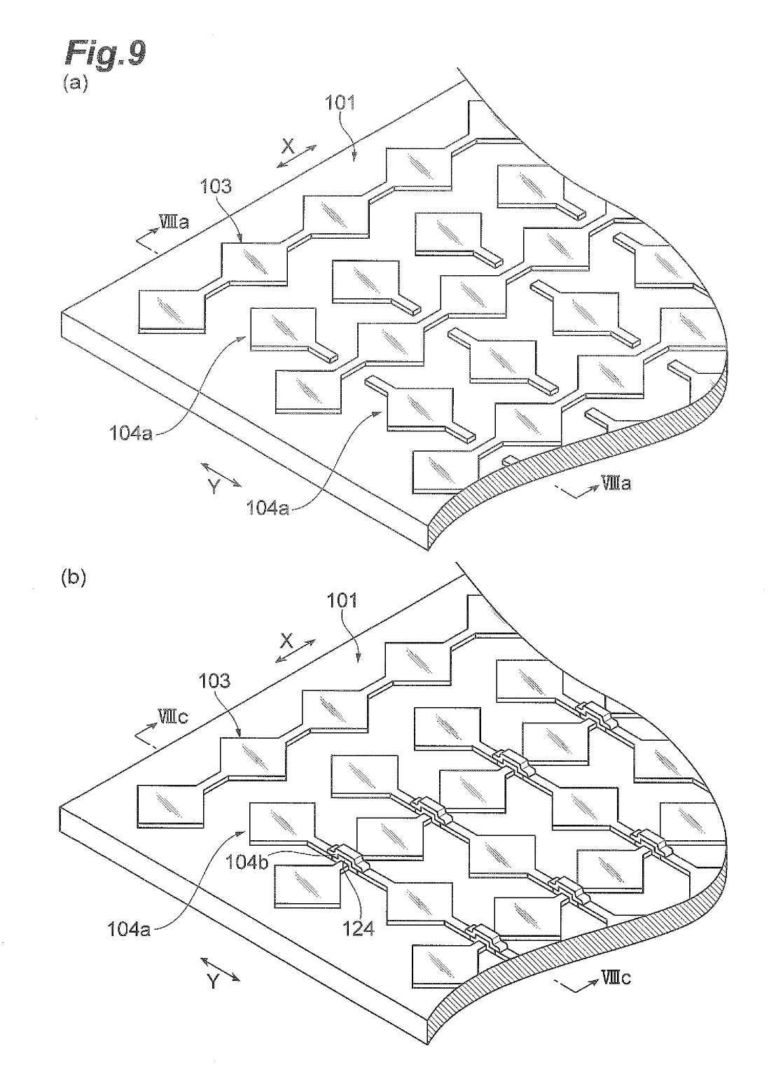

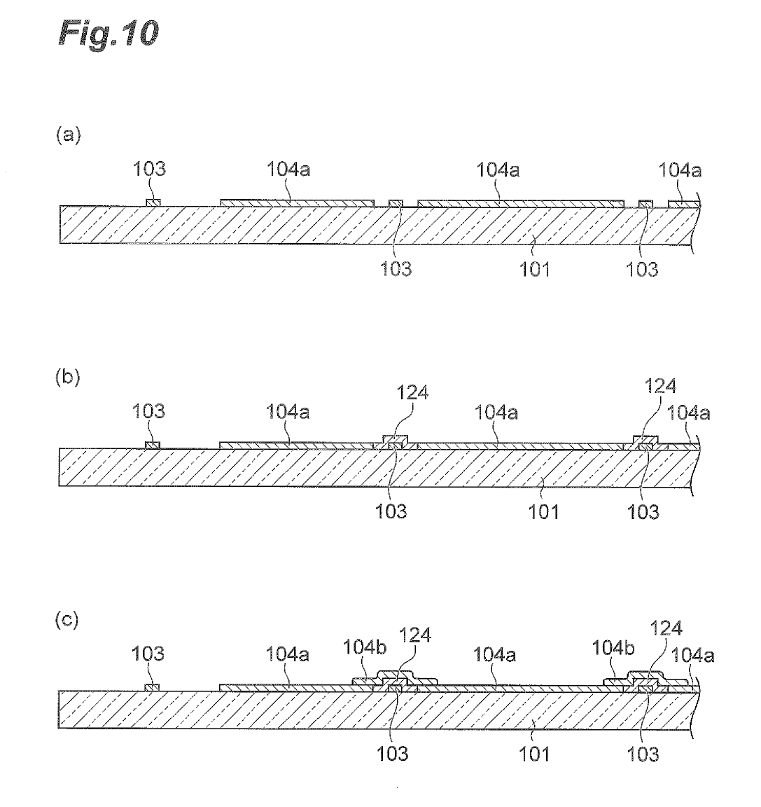

In the method of manufacturing a capacitive touch panel, for example, a substrate may be used in which the transparent electrodes (coordinates of X position) 103 and part of transparent electrodes, which later serve as the transparent electrodes 104 detecting the coordinate of Y position, are preliminarily formed on the transparent substrate 101 by a known method using a transparent conductive material. FIG. 9 is a drawing for describing one example of the method of manufacturing a capacitive touch panel having transparent electrodes present on the same plane; FIG. 9(a) is a partially cutout perspective view illustrating a substrate provided with transparent electrodes, and FIG. 9(b) is a partially cutout perspective view illustrating the resulting capacitive touch panel. FIG. 10 is a drawing for describing one example of the method of manufacturing a capacitive touch panel having transparent electrodes present on the same plane.

First, a substrate having transparent electrodes (coordinates of X position) 103 and parts 104a of the transparent electrodes preliminarily formed thereon as illustrated in FIG. 9(a) and FIG. 10(a) is prepared, and a photosensitive layer comprising the photosensitive resin composition according to the present embodiment is disposed on parts of the transparent electrodes 103 (transparent electrodes 103 between parts 104a), and is subjected to exposure and development to dispose an insulation film 124 (FIG. 10(b)). Subsequently, a conductive pattern is formed by a known method. This conductive pattern can form bridge portions 104b of the transparent electrodes 104 (FIG. 10(c)). The parts 104a of the transparent electrodes preliminarily formed can be conducted by these bridge portions 104b of the transparent electrodes, and the transparent electrodes (coordinates of Y position) 104 are formed. The photosensitive resin composition and the photosensitive element according to the present invention are suitably used for formation of the resin cured film pattern as an insulation film in the structural component.

The transparent electrodes preliminarily formed may be formed by a known method using ITO, for example. The drawing wirings 105a and 105b can be formed by known methods using a transparent conductive material or a metal such as Cu and Ag. Alternatively, a substrate having the drawing wirings 105a and 105b preliminarily formed thereon may be used.

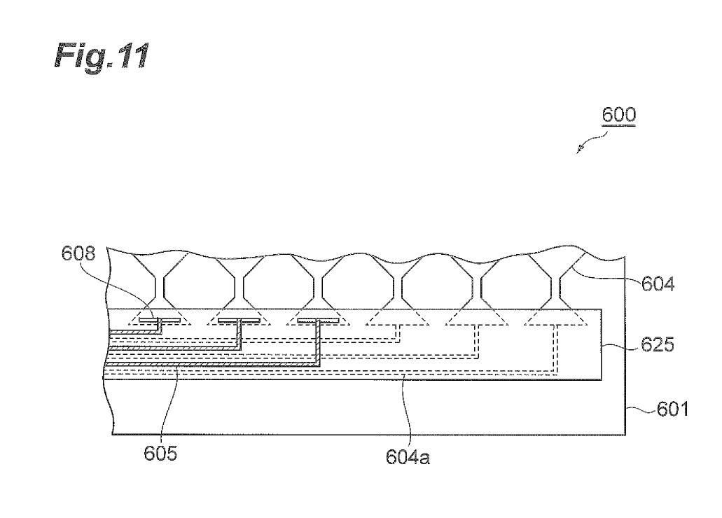

FIG. 11 is a partial plan view illustrating one example of another capacitive touch panel. The configuration illustrated in FIG. 11 is intended for a reduction in the frame of the touch panel. A touch panel 600 illustrated in FIG. 11 has a transparent substrate 601, transparent electrodes 604, wirings (transparent electrode wirings) 604a, drawing wirings 605, and an insulation film 625. The transparent electrodes 604 and the wirings 604a are disposed on the transparent substrate 601. The wirings 604a extend from the transparent electrodes 604. The insulation film 625 is disposed on ends of the transparent electrodes 604 and the wirings 604a. The drawing wirings 605 are disposed on the insulation film 625. Openings 608 are formed in the insulation film 625 in upper portions of ends of part of the transparent electrodes 604. The transparent electrodes 604 and the drawing wirings 605 are connected and conducted to each other through the openings 608. The photosensitive resin composition and the photosensitive element according to the present invention are suitably used for formation of the resin cured film pattern as a partial insulation film for the structure above.

### EXAMPLES

The present invention will now be more specifically described using Examples. The present invention will not be limited to the Examples below.

[Preparation of Binder Polymer Solution (A1)]

(1) shown in Table 1 was placed in a flask including a stirrer, a reflux cooler, an inert gas introducing port, and a thermometer, and was heated under a nitrogen gas atmosphere to 80° C.; while the reaction temperature was kept at 80° C.±2° C., (2) shown in Table 1 was uniformly dropped over 4 hours. After dropping of (2), stirring was continued at 80° C.±2° C. for 6 hours to obtain a solution (solid content: 45% by mass) (A1) of a binder polymer having a weight average molecular weight of about 65000 and an acid value of 78 mgKOH/g.

[Preparation of Binder Polymer Solution (A2)]

The operation was performed in the same manner as in (A1) to obtain a solution (solid content: 45% by mass) (A2) of a binder polymer having a weight average molecular weight of about 80000 and an acid value of 115 mgKOH/g.

[Preparation of Binder Polymer Solution (A3)]

The operation was performed in the same manner as in (A1) to obtain a solution (solid content: 45% by mass) (A3) of a binder polymer having a weight average molecular weight of about 60000 and an acid value of 91 mgKOH/g.

[Preparation of Binder Polymer Solution (A4)]

The operation was performed in the same manner as in (A1) to obtain a solution (solid content: 45% by mass) (A4) of a binder polymer having a weight average molecular weight of about 90000 and an acid value of 91 mgKOH/g.

TABLE 1

| | Amount of compounding (parts by mass) | | | |
|---|---|---|---|---|
| Items | A1 | A2 | A3 | A4 |
| Propylene glycol | 62 | 62 | 60 | 60 |
| monomethyl ether | | | | |
| Toluene | 62 | 62 | 40 | 40 |
| Methacrylic acid | 12 | 17.5 | 14 | 14 |
| Methyl methacrylate | 58 | 52.5 | 56 | 61 |
| Ethyl acrylate | 30 | 30 | 30 | 25 |
| 2,2′-Azobis | 1.5 | 1.2 | 1 | 0.6 |
| (isobutyronitrile) | | | | |
| Weight average molecular | 65,000 | 80,000 | 60,000 | 90,000 |
| weight (Mw) | | | | |
| Acid value (mgKOH/g) | 78 | 115 | 91 | 91 |
| Tg (° C.) | 60 | 65 | 62 | 70 |

The weight average molecular weight (Mw) was measured by gel permeation chromatography (GPC), and was derived from conversion using calibration curves of standard polystyrenes. The conditions on GPC are shown below.

GPC conditions

pump: Hitachi L-6000 (manufactured by Hitachi, Ltd., product name)

columns: Gelpack GL-R420, Gelpack GL-R430, and Gelpack GL-R440 (manufactured by Hitachi Chemical Company, Ltd., product name)

specification of columns: diameter of 10.7 mm×300 mm

eluent: tetrahydrofuran

sample concentration: 120 mg of a resin solution having a non-volatile component (NV) of 50% by mass is extracted, and is dissolved in 5 mL of THF

amount of injection: 200 μL

pressure: 4.9 MPa

temperature for measurement: 40° C.

flow rate: 2.05 mL/min

detector: Hitachi L-3300 RI (manufactured by Hitachi, Ltd., product name)

[Method of Measuring Acid Value]

The acid value was measured as follows. First, a solution of a binder polymer was heated at 130° C. for 1 hour to remove volatile components, thereby obtaining a solid content. 1.0 g of a polymer whose acid value was to be measured was precisely weighed, 30 g of acetone was then added to the polymer to uniformly dissolve the polymer. Next, an indicator phenolphthalein was added to the solution in an appropriate amount to perform titration using an aqueous solution of 0.1 N KOH. The number of milligrams of KOH needed to neutralize the solution of the binder polymer in acetone was calculated from the following expression to determine the acid value:

acid value=0.1×Vf×56.1/(Wp×I/100)

where Vf represents the amount (mL) of KOH in titration; Wp represents the weight (g) of the polymer solution measured; and I represents the proportion (% by mass) of the non-volatile component in the polymer solution measured.

### Example 1

### Preparation of Photosensitive Resin Composition Solution (V-1) for Forming Cured Film

The materials shown in Table 2 were mixed with a stirrer for 15 minutes to prepare Photosensitive resin composition solution (V-1) for forming a cured film.

TABLE 2

| | | Amount of compounding amount |
|---|---|---|
| Component | Materials | (parts by mass) |
| (A) | (A1) | 60 |
| (B) | T-1420 (T) | 40 |
| (C) | OXE01 | 1.7 |
| Others | B6030 | 0.4 |
| | Methyl ethyl ketone | 50 |

[Preparation of Photosensitive Element (E-1) for Forming Cured Film]

A poly(ethylene terephthalate) film having a thickness of 50 μm was used as a support film, Photosensitive resin composition solution (V-1) was uniformly applied onto the support film with a comma coater, and the solvent was removed by drying with a 100° C. hot air convection dryer for 3 minutes to form a photosensitive layer (photosensitive resin composition layer) composed of a photosensitive resin composition. The thickness of the obtained photosensitive layer was 5 μm.

Next, a polyethylene film having a thickness of 25 μm as a cover film was further bonded onto the obtained photosensitive layer to prepare Photosensitive element (E-1) for forming a cured film.

[Measurement of Transmittance of Cured Film]

While the polyethylene film as the cover film for the obtained Photosensitive element (E-1) was being peeled, the photosensitive layer was laminated on a glass substrate having a thickness of 1 mm with a laminator (manufactured by Hitachi Chemical Company, Ltd., trade name: HLM-3000) on the conditions, i.e., at a roll temperature of 120° C., a substrate feeding rate of 1 m/min, and a press bonding pressure (cylinder pressure) of 4×10⁵ Pa (line pressure at this time of 9.8×10³ N/m because a substrate having a thickness of 1 mm and a length of 10 cm×a width of 10 cm was used) to prepare a laminate in which the photosensitive layer and the support film were laminated on the glass substrate.

Next, the photosensitive layer of the obtained laminate was irradiated with ultraviolet light using a parallel light exposure machine (manufactured by ORC MANUFACTURING CO., LTD., EXM1201) from above the photosensitive layer at an amount of exposure of 5×10² J/m² (measured value at i rays (wavelength: 365 nm)), and the support film was then removed to obtain a sample for measuring the transmittance having a protective film (photo-cured film) composed of a cured product of the photosensitive layer having a thickness of 5.0 μm.

Next, the obtained sample was measured for the visible light ray transmittance with a UV-visible spectrophotometer (U-3310) manufactured by Hitachi High-Tech Fielding Corporation in a wavelength band for measurement of 400 to 700 nm. The obtained transmittance at a wavelength of 400 nm of the photosensitive layer was 97% at a wavelength of 700 nm, 96% at a wavelength of 550 nm, and 94% at a wavelength of 400 nm; the minimum value of the transmittance at 400 to 700 nm was 94%; high transmittance could be ensured. Also in Examples 2 to 4, the visible light ray transmittance of 90% or more was shown in the wavelength band for measurement of 400 to 700 nm.

[Measurement of b* of Cured Film]

While the polyethylene film as the protective film for the obtained Photosensitive element (E-1) was being peeled, the photosensitive layer was laminated on a glass substrate (b*: 0.1 to 0.2) having a thickness of 0.7 mm with a laminator (manufactured by Hitachi Chemical Company, Ltd., trade name: HLM-3000) on the conditions, i.e., at a roll temperature of 120° C., a substrate feeding rate of 1 m/min, and a press bonding pressure (cylinder pressure) of 4×10⁵ Pa (line pressure at this time of 9.8×10³ N/m because a substrate having a thickness of 1 mm and a length of 10 cm×a width of 10 cm was used) to prepare a laminate in which the photosensitive layer and the support film were laminated on the glass base material.

Next, the obtained photosensitive layer was irradiated with ultraviolet light using a parallel light exposure machine (manufactured by ORC MANUFACTURING CO., LTD., EXM1201) from above the photosensitive layer at an amount of exposure of 5×10² J/m² (measured value at i rays (wavelength: 365 nm)), the support film was then removed, and the photosensitive layer was further irradiated with ultraviolet light from above the photosensitive layer at an amount of exposure of 1×10⁴ J/m² (measured value at i rays (wavelength: 365 nm)) to obtain a sample for measuring b* having a protective film (photo-cured film) composed of a cured product of the photosensitive layer having a thickness of 5.0 μm.

Next, the obtained sample was measured for the b* in the CIELAB color system using a spectrocolorimeter (CM-5) manufactured by KONICA MINOLTA, INC. with a D65 light source set at a viewing angle of 2°.

The b* of the cured film was 0.44, and it was verified that the cured film has good b*. Also in Examples 2 to 4, b* sufficiently satisfied the range of −0.2 to 1.0.

[Saline Water Spray Test on Cured Film]

While the polyethylene film as the cover film for the obtained Photosensitive element (E-1) was being peeled, the photosensitive layer was laminated on a polyimide film with sputtered copper (manufactured by TORAY ADVANCED FILM Co., Ltd.) with a laminator (manufactured by Hitachi Chemical Company, Ltd., trade name: HLM-3000) on the conditions, i.e., at a roll temperature of 120° C., a substrate feeding rate of 1 m/min, and a press bonding pressure (cylinder pressure) of 4×10⁵ Pa (line pressure at this time of 9.8×10³ N/m because a substrate having a thickness of 1 mm and a length of 10 cm×a width of 10 cm was used) to prepare a laminate in which the photosensitive layer and the support film were laminated on the sputtered copper.

Next, the photosensitive layer of the obtained laminate was irradiated with ultraviolet light using a parallel light exposure machine (manufactured by ORC MANUFACTURING CO., LTD., EXM1201) from above the photosensitive layer at an amount of exposure of 5×10² J/m² (measured value at i rays (wavelength: 365 nm)), the support film was then removed, and the photosensitive layer was further irradiated with ultraviolet light from above the photosensitive layer at an amount of exposure of 1×10⁴ J/m² (measured value at i rays (wavelength: 365 nm)) to obtain a sample for evaluation on resistance against saline water in which a protective film (photo-cured film) composed of a cured product of the photosensitive layer having a thickness of 5.0 μm was formed.

Next, with reference to JIS (Z 2371), using a saline water spray tester (manufactured by Suga Test Instruments Co., Ltd., STP-90V2), the sample was placed in a test tank, and 50 g/L saline water (pH=6.7) was sprayed onto the sample at a test tank temperature of 35° C. and an amount of spray of 1.5 mL/h for 48 hours. After spraying was completed, saline water was wiped off, the state of the surface of the sample for evaluation was observed to evaluate according to the following criteria for evaluation.

A: no change is found on the surface of the protective film.
B: slight traces are found on the surface of the protective film while copper does not change.
C: traces are found on the surface of the protective film while copper does not change.
D: traces are found on the surface of the protective film and the color of copper changes.
The state of the surface of the sample for evaluation was observed; no change on the surface of the protective film was found, and the sample was rated as A.

[Mandrel Test]

While the polyethylene film of the obtained Photosensitive element (E-1) was being peeled, the photosensitive layer was laminated on a poly(ethylene terephthalate) film having a thickness of 50 μm on the conditions, i.e., at a roll temperature of 100° C., a substrate feeding rate of 0.6 m/min, and a press bonding pressure (cylinder pressure) of 0.5 MPa to prepare a laminate in which the photosensitive layer and the support film were laminated on the poly(ethylene terephthalate) film.

After the obtained laminate was prepared, a photomask was disposed over the support film, and the laminate was irradiated with ultraviolet light using a parallel light exposure machine (manufactured by ORC MANUFACTURING CO., LTD., EXM1201) from vertical above to the surface of the photomask at an amount of exposure of 5×10² J/m² (measured value at i rays (wavelength: 365 nm)) in the form of an image.

Next, the support film laminated on the photosensitive layer was removed, and the photosensitive layer was further irradiated with ultraviolet light from above the photosensitive layer at an amount of exposure of 1×10⁴ J/m² (measured value at i rays (wavelength: 365 nm)) to obtain a sample for a mandrel test in which a protective film (photo-cured film) composed of a cured product of the photosensitive layer having a thickness of 5.0 μm was formed.

Next, with reference to JIS (K5400), a mandrel test was performed. The sample for a test was cut into a size of 1.5 cm×4.0 cm with a pair of scissors, and 100 g of a weight was attached to one surface of a tester; the sample was set with the protective film side facing upward; the sample was bent 180° around a cylinder, and was then returned to the original position; the protective film side of the sample was observed with a microscope to evaluate crack resistance according to the following criteria for evaluation.

A: no crack is found in the protective film where a cylinder of ≦φ2.0 mm is used.
B: no crack is found in the protective film where a cylinder of φ3.0 to φ4.0 mm is used.
C: no crack is found in the protective film where a cylinder of ≧φ5.0 is used.

The state of the surface of the protective film of the sample for evaluation was observed; no crack was found even if a cylinder of φ2.0 mm was used, and the sample was rated as A.

[Measurement of Degree of Moisture Permeation]

The obtained Photosensitive resin composition solution (V-1) was uniformly applied onto a poly(ethylene terephthalate) film having a thickness of 50 μm with an applicator to prepare Photosensitive element (E-2) having a thickness of 40 μm. The obtained Photosensitive element (E-2) was laminated on a No. 5C filter paper (manufactured by Advantec) on the conditions, i.e., at a roll temperature 80° C., a substrate feeding rate of 0.6 m/min, and a press bonding pressure (cylinder pressure) of 0.5 MPa such that the photosensitive layer was in contact with the filter paper to prepare a laminate in which the photosensitive layer and the poly(ethylene terephthalate) film were laminated on the No. 5C filter paper.

After the obtained laminate was prepared, using a parallel light exposure machine (manufactured by ORC MANUFACTURING CO., LTD., EXM1201), the laminate was irradiated with ultraviolet light at an amount of exposure of 5×10² J/m² (measured value at i rays (wavelength: 365 nm)) from vertical above to the surface of the poly(ethylene terephthalate) film in the form of an image.

Next, the support film laminated on the photosensitive layer was removed, and the photosensitive layer was further irradiated with ultraviolet light from above the photosensitive layer at an amount of exposure of 1×10⁴ J/m² (measured value at i rays (wavelength: 365 nm)) to obtain a sample for measurement of degree of moisture permeation in which a protective film (photo-cured film) composed of a cured product of the photosensitive layer having a thickness of 40 μm was formed.

Next, with reference to JIS (Z0208), a cup method was performed as measurement of degree of moisture permeation. About 20 g of dry calcium chloride was placed in a cup for measurement, and was covered with a circular sample cut from the sample for a test into a size of about φ70 mm with a pair of scissors; the cup was left in a thermo-hygrostat on the conditions, i.e., at 60° C. and 90% RH for 24 hours. The degree of moisture permeation was calculated from a change in weight before and after the cup was left, and the moisture permeability was evaluated according to the following criteria for evaluation.

A: degree of moisture permeation ≦450 (g/m²·24 h).
B: 450<degree of moisture permeation ≦550 (g/m²·24 h).
C: 550<degree of moisture permeation ≦650 (g/m²·24 h).
D: degree of moisture permeation >650 (g/m²·24 h).

In Example 1, the degree of moisture permeation was less than 450 (g/m²·24 h), and therefore the sample was rated as A.

### Examples 2 to 4

Photosensitive elements were prepared in the same manner as in Example 1 except that photosensitive resin composition solutions shown in Table 3 (units for the numeric values in Table are parts by mass) were used, and were subjected to the saline water spray test, the mandrel test, and the determination of degree of moisture permeation. As shown in Table 3, in Examples 1 to 4, good results were obtained in the evaluation of resistance against saline water, the mandrel test, and the determination of degree of moisture permeation.

TABLE 3

| | Items | Example | | | | Comparative Example | | | |
|---|---|---|---|---|---|---|---|---|---|
| | Names of materials | 1 | 2 | 3 | 4 | 1 | 2 | 3 | 4 |
| Binder polymer | A1 | 60 | — | — | — | 60 | 60 | 60 | 60 |
| | A2 | — | 60 | — | — | — | — | — | — |
| | A3 | | | 60 | | — | — | — | — |
| | A4 | | | | 60 | — | — | — | — |
| Photopolymerizable | T-1420 (T) | 40 | 40 | 40 | 40 | — | — | — | — |
| compound | | | | | | | | | |
| Other | A-TMMT | — | — | — | — | 40 | — | — | — |
| photopolymerizable | RP-1040 | — | — | — | — | — | 40 | — | — |
| compounds | BPE-500 | — | — | — | — | — | — | 40 | — |
| | 4G | — | — | — | — | — | — | — | 40 |
| Photopolymerization | OXE01 | 1.7 | 1.7 | 1.7 | 1.7 | 1.7 | 1.7 | 1.7 | 1.7 |
| initiator | | | | | | | | | |
| Others | AW500 | 0.1 | 0.1 | 0.1 | 0.1 | 0.1 | 0.1 | 0.1 | 0.1 |
| | SH-30 | 0.07 | 0.07 | 0.07 | 0.07 | 0.07 | 0.07 | 0.07 | 0.07 |
| | MEK | 50 | 50 | 50 | 50 | 50 | 50 | 50 | 50 |

| | | | | | | | | |
|---|---|---|---|---|---|---|---|---|
| Resistance against saline water | A | B | B | B | C | C | D | D |
| Crack resistance | A | B | B | B | B | A | C | C |
| Moisture permeability | A | B | B | B | B | C | D | D |

Component (A): Binder Polymer

(A1): methacrylic acid/methyl methacrylate/ethyl acrylate=12/58/30 (mass ratio), acid value: 78 (mgKOH/g)
(A2): methacrylic acid/methyl methacrylate/ethyl acrylate=17.5/52.5/30 (mass ratio), acid value: 115 (mgKOH/g)
(A3): methacrylic acid/methyl methacrylate/ethyl acrylate=14/56/30 (mass ratio), acid value: 91 (mgKOH/g)
(A4): methacrylic acid/methyl methacrylate/ethyl acrylate=14/61/25 (mass ratio), acid value: 91 (mgKOH/g)

Component (B): Photopolymerizable Compound

T-1420(T): ditrimethylolpropane tetraacrylate (manufactured by NIPPON KAYAKU Co., Ltd.)

### Other Photopolymerizable Compounds

A-TMMT: pentaerythritol tetraacrylate (manufactured by Shin Nakamura Chemical Co., Ltd.)
TMPTA: trimethylolpropane triacrylate (manufactured by NIPPON KAYAKU Co., Ltd.),
RP-1040: EO-modified pentaerythritol tetraacrylate (manufactured by NIPPON KAYAKU Co., Ltd.)
BPE-500: ethoxylated bisphenol A dimethacrylate (manufactured by Shin Nakamura Chemical Co., Ltd.)
4G: polyethylene glycol #200 dimethacrylate (manufactured by Shin Nakamura Chemical Co., Ltd.)

### Component (C): Photopolymerization Initiator

### OXE01:

1,2-octanedione, 1-[4-(phenylthio)-, 2-(o-benzoyloxime)] (manufactured by BASF SE, trade name: IRGACURE OXE 01)
Other AW-500: 2,2′-methylene-bis(4-ethyl-6-Tert-butylphenol) (Antage W-500, manufactured by Kawaguchi Chemical Industry Co., LTD.)
SH-30: organic modified silicone oil (manufactured by Dow Corning Toray Co., Ltd.)
methyl ethyl ketone: manufactured by Tonen Chemical Corporation

### REFERENCE SIGNS LIST

1 . . . photosensitive element, 10 . . . support film, 20 . . . photosensitive layer, 22, 122, 123 . . . protective film, 30 . . . protection film, 100 . . . transparent substrate, 101, 601 . . . transparent substrate, 102 . . . touch screen, 103 . . . transparent electrode (coordinate of X position), 104 . . . transparent electrode (coordinate of Y position), 104a . . . part of transparent electrode, 104b . . . bridge portion of transparent electrode, 105, 105a, 105b . . . drawing wiring, 106 . . . connection electrode, 107 . . . connection terminal, 110, 120 . . . electrode for touch panels, 124, 625 . . . insulation film, 130 . . . photomask, 200, 600 . . . touch panel, 604 . . . transparent electrode, 604a . . . wiring (transparent electrode wiring), 608 . . . opening.

1. A method of manufacturing a transparent base material provided with a cured film, comprising: disposing a photosensitive layer on a transparent base material, the photosensitive layer composed of a photosensitive resin composition containing a binder polymer, a photopolymerizable compound containing at least one (meth)acrylate compound selected from the group consisting of (meth)acrylate compounds having a skeleton derived from ditrimethylolpropane and (meth)acrylate compounds having a skeleton derived from diglycerol, and a photopolymerization initiator; curing a predetermined portion of the photosensitive layer through irradiation with active light rays; and then removing portions of the photosensitive layer other than the predetermined portions to form a cured film composed of a cured product of the photosensitive resin composition, the cured film coating part or all of the base material.

2. The method of manufacturing a transparent base material provided with a cured film according to claim 1, wherein the (meth)acrylate compound is a compound having four or more (meth)acryloyl groups.

3. The method of manufacturing a transparent base material provided with a cured film according to claim 1, wherein the photopolymerization initiator contains an oxime ester compound and/or a phosphine oxide compound.

4. The method of manufacturing a transparent base material provided with a cured film according to claim 1, wherein a photosensitive element comprising a support film and a photosensitive layer composed of the photosensitive resin composition and disposed on the support film is prepared, and the photosensitive layer of the photosensitive element is transferred onto the base material to dispose the photosensitive layer.

5. A photosensitive resin composition comprising:
a binder polymer;
a photopolymerizable compound containing at least one compound selected from the group consisting of (meth)acrylate compounds having a skeleton derived from ditrimethylolpropane and (meth)acrylate compounds having a skeleton derived from diglycerol; and
a photopolymerization initiator,
the composition being used to form a cured film on a transparent base material.

6. The photosensitive resin composition according to claim 5, wherein the (meth)acrylate compound is a compound having four or more (meth)acryloyl groups.

7. The photosensitive resin composition according to claim 5, wherein the photopolymerization initiator contains an oxime ester compound and/or a phosphine oxide compound.

8. A photosensitive element comprising:
a support film; and
a photosensitive layer composed of the photosensitive resin composition according to claim 5 and disposed on the support film.

9. The photosensitive element according to claim 8, wherein a thickness of the photosensitive layer is 10 μm or less.

10. An electrical component comprising a transparent base material provided with a cured film obtained by the method according to claim 1.
